(19) United States
(12) Patent Application Publication
(10) Pub. No.: US 2002/0064921 A1
(43) Pub. Date: May 30, 2002

(54) Semiconductor integrated circuit device and a method of manufacturing the same

(75) Inventors: Masataka Kato, Koganei (JP); Toshiaki Nishimoto, Tama (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 09/967,928

(22) Filed: Oct. 2, 2001

(30) Foreign Application Priority Data
Oct. 13, 2000 (JP) 2000-313334

(51) Int. Cl. H01L 21/336; H01L 21/425

(52) U.S. Cl. 438/306; 438/533

(57) ABSTRACT

In a flash memory having enhanced reliability, each memory cell has a floating gate electrode which is formed on a semiconductor substrate by being interposed by a gate insulation film, a control gate electrode which is formed on the floating gate electrode by being interposed by an inter-layer film, a pair of n-type semiconductor regions (source regions) formed on the semiconductor substrate to confront two sidewise portions of the floating gate electrode, an n-type semiconductor region (drain region) formed beneath the n-type semiconductor region pair by being interposed by channel well regions, and a common p-well formed beneath the semiconductor region. The n-type semiconductor regions and channel well regions make up the DD structure.

### BACKGROUND OF THE INVENTION

The present invention relates to a semiconductor integrated circuit device and its fabrication technique, and particularly to a technique useful for a semiconductor integrated circuit device having an electrically-rewritable parallel-array nonvolatile memory.

Nonvolatile memories which can write and erase data electrically are advantageous in their capability of data rewriting while being mounted on printed circuit boards or the like, and are used widely in various appliances.

Particularly, the electrically erasable programmable read-only memory (EEPROM) of the block erasure type, which will be called “flash memory” hereinafter, has a function of erasing data of a certain range of a memory array (all memory cells or a group of memory cells of a memory array) at once. The flash memory is in progress of cell size reduction owing to its 1-transistor laminated gate structure, and is expected to have an increased integration density.

In the 1-transistor laminated gate structure, a nonvolatile memory cell is basically formed of one double-layer-gate metal insulator semiconductor field effect transistor (MISFET). The double-layer-gate MISFET is fabricated by forming a floating gate electrode on a semiconductor substrate through a tunneling oxide film and laminating a control gate electrode on it through an inter-layer film. Data storing and erasure take place by the injection of electrons into the floating gate electrode and the release of electrons from the electrode.

In regard to the flash memory, the structure and usage of a parallel-type flash memory having memory arrays is disclosed in U.S. Pat. No. 5,793,678 corresponding Japanese Application laid-open No.Hei 8(1996)-279566, in which numerous memory cells are formed in matrix arrangement on a semiconductor substrate, with memory cells of each column having their source regions connected in parallel and their drain regions connected in parallel, and word lines are formed to extend along the rows. The flash memory of this type is generally known to be an AND-type flash memory.

### SUMMARY OF THE INVENTION

Data writing and erasure of the above-mentioned AND-type flash memory take place by utilization of the electron tunneling phenomenon (Fowler-Nordheim phenomenon, or will be called here “FN phenomenon”) in the tunneling oxide film of memory cell, by which electrons are injected into the floating gate electrode or electrons are released from the electrode. Injection of electrons into the floating gate electrode is defined to be data writing and release of electrons from the electrode is defined to be data erasure, for example.

For writing data, a certain positive voltage (e.g.,18 V) is applied to the selected word line and a certain voltage lower than the positive voltage is applied to the drain region. The source region is left open. Writing of “0” (write selected) and writing of “1” (write unselected) to each memory cell is dependent on the voltage level applied to each drain region. Specifically, when the drain region is brought to “0” V for example, the electric field applied to the tunneling oxide film increases to foster the emergence of FN phenomenon, causing electrons to be injected into the floating gate electrode, and “0” is written to the memory cell. The threshold voltage rises in this case. Conversely, when the drain region is brought to a certain positive voltage (e.g.,6 V), the electric field applied to the tunneling oxide film decreases to suppress the emergence of FN phenomenon, precluding electrons from being injected into the floating gate electrode, and “0” is written to the memory cell. The threshold voltage falls in this case.

For reading out data, a voltage (e.g.,3 V) is applied to the selected word line and a voltage (e.g.,0 V) is applied to unselected word lines, and, in addition, a voltage (e.g.,1 V) is applied to the drain region and a voltage (e.g.,0 V) is applied to the source region. Since the bit line voltage falls when the threshold voltage of memory cell is low relatively and the bit line retains a voltage (e.g.,1 V) when the threshold voltage is high relatively, data can be read out of each memory cell by detecting the voltage of each bit line.

For erasing data, a certain negative voltage (e.g., −1 V) is applied to the selected word line and the source and drain regions are brought to a certain voltage (e.g.,0 V) higher than the negative voltage. The FN phenomenon emerges over the entire tunneling oxide film, causing the floating gate to release electrode electrons, and the memory cell has its threshold voltage set in a relatively low voltage range.

However, the inventors of the present invention have found a problem of degraded reliability of memory cells due to the deterioration of breakdown voltage of particularly the drain region caused by repetitive data read/write operations of an AND-type flash memory of higher density integration.

For the data readout operation, a source-to-drain breakdown voltage of 1 V or higher is necessary in order to prevent the punch-through phenomenon between the source and drain regions, and for the data write operation, a breakdown voltage of 6 V or higher is required for the drain region.

The inventors of the present invention have studied a memory cell formed of the conventional lateral double-layer-gate MISFET having its source and drain regions formed to confront the gate electrode, and found that it is possible for the memory cell having a gate length of about 0.2 μm at the contact of the floating gate electrode to the tunneling oxide film to keep the above-mentioned breakdown voltages. It is even possible for a memory cell having a gate length of about 0.16 μm to keep a punch-through breakdown voltage of 1 V or higher based on the provision of a concentrated impurity region (channel stopper layer), which is opposite in conductivity type to the drain region, to surround the drain region thereby to shorten the depletion layer extending from the drain region to the source region.

Nevertheless, if the gate length at the contact of the floating gate electrode to the tunneling oxide film further decreases to about 0.1 μm in the progress of microstructuring of memory cells, it will become difficult to keep a punch-through breakdown voltage of 1 V or higher for data readout even by use of the above-mentioned concentrated impurity region (channel stopper layer). Even in case the punch-through breakdown voltage is raised by a higher concentration of channel stopper layer (e.g.,1×10¹⁸ cm⁻³ or more), the junction breakdown voltage of the drain region for data writing will deteriorate significantly.

Accordingly, it is an object of the present invention to provide a technique capable of improving the reliability of the flash memory based on the retention of the breakdown voltage between the source and drain regions and the enhancement of the breakdown voltage of the pn junction of the drain region.

Another object of the present invention is to provide a technique capable of accomplishing the higher-density integration of the flash memory.

These and other objects and novel features of the present invention will become apparent from the following description taken in conjunction with the accompanying drawings.

Among the affairs of the present invention disclosed in this specification, representatives are briefed as follows.

The inventive semiconductor integrated circuit device has a plurality of memory cells formed in matrix arrangement on a semiconductor substrate, and each memory cell includes a floating gate electrode which is formed on the semiconductor substrate by being interposed by a tunneling oxide film, a control gate electrode which is formed on the floating gate electrode by being interposed by an inter-layer film, a pair of source regions and a drain region which are formed beneath the floating gate electrode on the semiconductor substrate, a channel well region which is located between the source regions and the drain region and surrounded by the drain region, and a common semiconductor region which is formed by being separated from the channel well region (channel formation region) by the drain region to have a pn junction with the drain region.

The inventive method of fabricating a semiconductor integrated circuit device includes a step of preparing a semiconductor substrate having a main surface, a step of implanting impurity of a first conductivity type into the substrate from the main surface thereby to form drain regions of the first conductivity type having a pn junction with a common semiconductor region, a step of forming floating gate electrodes through a tunneling oxide film on the main surface of the portions of substrate where the drain regions are formed, a step of implanting impurity of a second conductivity type into the portions of substrate where the drain regions are formed from at least one end of the floating gate electrodes by using the floating gate electrodes as a mask thereby to form channel formation regions (channel well regions) in the drain regions, and a step of implanting impurity of the first conductivity type into the portions of substrate where the channel formation regions are formed from at least the one end of the floating gate electrodes by using the floating gate electrodes as a mask thereby to form source regions in the channel formation regions.

The inventive method of fabricating a semiconductor integrated circuit device includes a step of forming p-wells and drain regions in a semiconductor substrate, a step of forming a tunneling oxide film on the substrate and thereafter working the lower conductor film for floating gate electrodes, which is deposited on the tunneling oxide film, along a first direction, a step of forming channel well regions and source regions in the substrate at two sidewise portions of the lower conductor film for floating gate electrodes, a step of forming separation grooves in the substrate by using a lower conductor film for first gate electrodes and an insulator film formed on the side walls of the lower conductor film as a mask and thereafter filling the separation grooves and recesses on the substrate main surface with an insulator film, a step of working the upper conductor film for floating gate electrodes, which is deposited on the lower conductor film, along the first direction, and a step of forming an inter-layer film on the higher conductor film and thereafter working a conductor film for control gate electrodes, which is deposited on the inter-layer film, the inter-layer film, the upper conductor film for floating gate electrodes and the lower conductor film along a second direction which intersects the first direction.

According to the above-mentioned schemes, a certain distance is kept between the source regions and the drain region even if the memory cell has a channel length of 0.1 μm or less, and it becomes possible to keep a source-to-drain punch-through breakdown voltage of 1 V or higher which is required for the data readout operation.

Based on the separation of the channel well region between the source and drain regions from the common p-well, the junction breakdown voltage between the drain region and the p-well can be set higher relatively to the source-to-drain punch-through breakdown voltage, and it becomes possible to keep a junction breakdown voltage of 6 V or higher for the data write operation.

The presence of the channel-doped layer facilitates the adjustment of threshold voltage and causes the current between a pair of source regions to flow deeply below the substrate surface, resulting in a reduced hot electron injection, and it becomes possible to prevent the decay of tunneling oxide film and the fluctuation of threshold voltage.

The source regions can have their width in channel direction and the separation grooves can have their width both reduced smaller than the minimum working dimension, while retaining the channel length to be the minimum working dimension for example, and it becomes possible to reduce the pitch of bit lines.

The drain region is formed deep in the substrate and allowed to have the setting of an intended impurity concentration independently of the source regions, and it becomes possible to have a relatively low resistivity of the drain region.

The channel formation region and source regions are formed by double diffusion in the drain region in auto-matching fashion by use of at least one end of the floating gate electrode as a mask for impurity implantation or diffusion, and it becomes possible to adjust the dimension of the channel formation region between the source and drain regions in auto-matching fashion by the double diffusion process.

### BRIEF DESCRIPTION OF THE DRAWINGS

FIG. 1 is a schematic circuit diagram showing part of the memory array included in the flash memory based on a first embodiment of this invention;

FIG. 2 is a plan view of a portion of the memory array shown in FIG. 1;

FIG. 3 is a cross-sectional diagram of the memory array taken along the line A-A of FIG. 2;

FIG. 4 is a cross-sectional diagram of the memory array taken along the line B-B of FIG. 2;

FIG. 5 is a cross-sectional diagram of the memory array taken along the line C-C of FIG. 2;

FIG. 6 is a brief cross-sectional diagram showing memory cells included in the memory array of FIG. 2;

FIG. 7 is a graph showing an example of the concentration profiles of the semiconductor regions of the memory cell included in the memory array of FIG. 2;

FIG. 8 is a graph showing the drain current vs. gate voltage relation of the memory cell shown in FIG. 6;

FIG. 9 is a brief cross-sectional diagram showing a variant example of memory cells included in the memory array of FIG. 2;

FIG. 10 is a brief cross-sectional diagram of memory cells used to explain the data readout operation;

FIG. 11 is a brief cross-sectional diagram of memory cells used to explain the data erase operation;

FIG. 12 is a brief cross-sectional diagram of memory cells used to explain the data write operation;

FIG. 13 is a plan view showing a portion of the flash memory based on the first embodiment of this invention at a fabrication step;

FIG. 14 is a cross-sectional diagram showing the portion of the flash memory at the same fabrication step as FIG. 13;

FIG. 15 is a cross-sectional diagram showing another portion of the flash memory at the same fabrication step as FIG. 13;

FIG. 16 is a cross-sectional diagram showing still another portion of the flash memory at the same fabrication step as FIG. 13;

FIG. 17 is a plan view showing the same portion of flash memory as FIG. 13 at the fabrication step which follows the step shown in FIG. 13 through FIG. 16;

FIG. 18 is a cross-sectional diagram showing the same portion of flash memory as FIG. 14 at the same fabrication step as FIG. 17;

FIG. 19 is a cross-sectional diagram showing the same portion of flash memory as FIG. 15 at the same fabrication step as FIG. 17;

FIG. 20 is a cross-sectional diagram showing the same portion of flash memory as FIG. 16 at the same fabrication step as FIG. 17;

FIG. 21 is a plan view showing the same portion of flash memory as FIG. 13 at the fabrication step which follows the step shown in FIG. 17 through FIG. 20;

FIG. 22 is a cross-sectional diagram showing the same portion of flash memory as FIG. 14 at the same fabrication step as FIG. 21;

FIG. 23 is a cross-sectional diagram showing the same portion of flash memory as FIG. 14 at the same fabrication step which follows the step shown in FIG. 21 and FIG. 22;

FIG. 24 is a plan view showing the same portion of flash memory as FIG. 13 at the fabrication step which follows the step shown in FIG. 23;

FIG. 25 is a cross-sectional diagram showing the same portion of flash memory as FIG. 14 at the same fabrication step as FIG. 24;

FIG. 26 is a cross-sectional diagram showing the same portion of flash memory as FIG. 15 at the same fabrication step as FIG. 24;

FIG. 27 is a cross-sectional diagram showing the same portion of flash memory as FIG. 16 at the same fabrication step as FIG. 24;

FIG. 28 is a cross-sectional diagram showing the same portion of flash memory as FIG. 14 at the fabrication step which follows the step shown in FIG. 24 through FIG. 27;

FIG. 29 is a cross-sectional diagram showing the same portion of flash memory as FIG. 15 at the same fabrication step as FIG. 28;

FIG. 30 is a cross-sectional diagram showing the same portion of flash memory as FIG. 16 at the same fabrication step as FIG. 28;

FIG. 31 is a plan view showing the same portion of flash memory as FIG. 13 at the fabrication step which follows the step shown in FIG. 28 through FIG. 30;

FIG. 32 is a cross-sectional diagram showing the same portion of flash memory as FIG. 14 at the same fabrication step as FIG. 31;

FIG. 33 is a cross-sectional diagram showing the same portion of flash memory as FIG. 14 at the fabrication step which follows the step shown in FIG. 31 and FIG. 32;

FIG. 34 is a cross-sectional diagram showing the same portion of flash memory as FIG. 14 at the fabrication step which follows the step shown in FIG. 33;

FIG. 35 is a cross-sectional diagram showing the same portion of flash memory as FIG. 15 at the same fabrication step as FIG. 34;

FIG. 36 is a cross-sectional diagram showing the same portion of flash memory as FIG. 16 at the same fabrication step as FIG. 34;

FIG. 37 is a plan view showing the same portion of flash memory as FIG. 13 at the fabrication step which follows the step shown in FIG. 34 through FIG. 36;

FIG. 38 is a cross-sectional diagram showing the same portion of flash memory as FIG. 15 at the same fabrication step as FIG. 37;

FIG. 39 is a cross-sectional diagram showing the same portion of flash memory as FIG. 16 at the same fabrication step as FIG. 37;

FIG. 40 is a cross-sectional diagram showing the same portion of flash memory as FIG. 15 at the fabrication step which follows the step shown in FIG. 37 through FIG. 39;

FIG. 41 is a cross-sectional diagram showing the same portion of flash memory as FIG. 16 at the same fabrication step as FIG. 40;

FIG. 42 is a cross-sectional diagram showing the same portion of flash memory as FIG. 16 at the fabrication step which follows the step shown in FIG. 40 and FIG. 41;

FIG. 43 is a cross-sectional diagram showing the same portion of flash memory as FIG. 16 at the fabrication step which follows the step shown in FIG. 42;

FIG. 44 is a cross-sectional diagram showing a portion of the memory array included in the flash memory based on a second embodiment of this invention;

FIG. 45 is a cross-sectional diagram showing a portion of the memory array included in the flash memory based on a third embodiment of this invention; and

FIG. 46 is a cross-sectional diagram showing a portion of the memory array included in the flash memory based on a fourth embodiment of this invention.

### DETAILED DESCRIPTION OF THE INVENTION

The embodiments of this invention will be explained in detail with reference to the drawings. Throughout the figures, items having the same functions are referred to by the common symbols, and explanation thereof are not repeated. In the following explanation, a metal oxide semiconductor field effect transistor will be termed MOSFET, and an n-channel MOSFET and p-channel MOSFET will be termed simply n-MOSFET and p-MOSFET, respectively.

Embodiment 1

The semiconductor integrated circuit device of this embodiment is a flash memory having a channel length of about 0.1 μm and a storage capacity of 1 gigabits (1 Gb) for example. The present invention is not confined to devices of 1 Gb however, but is applicable to various devices having storage capacities of less than 1 Gb, e.g.,512 Mb, or more than 1 Gb.

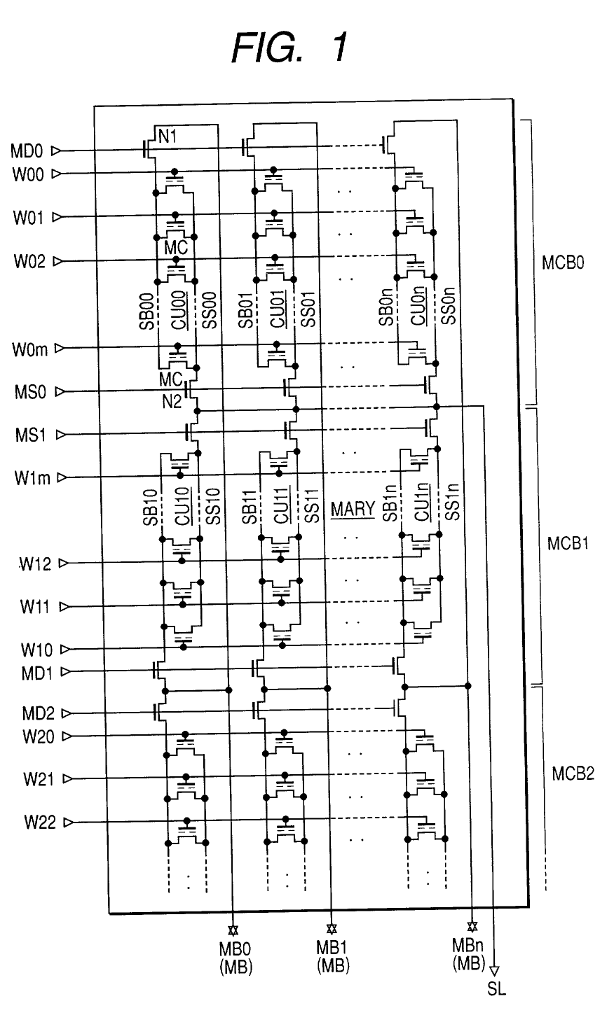

FIG. 1 shows schematically part of the memory array included in the flash memory of this embodiment. The structure of the memory array will be explained specifically on this figure.

The memory array includes memory cell blocks MCB0-MCBp of p+1 in number (FIG. 1 shows only memory cell blocks MCB0, MCB1 and MCB2 and their associated items). Each of these memory cell blocks has word lines of m+1 in number, i.e., W00-W0m through Wp0-Wpm, correspondingly, running in parallel to one another in the horizontal direction on the drawing, and has main bit lines MB0-MBn of n+1 in number running in parallel to one another in the vertical direction on the drawing. Located virtually at the intersections of these word lines and main bit lines are memory cells (MC) of the double-layer-gate type of m+1 by n+1 in number.

The memory array has the parallel array structure called AND-type in general for example, and the memory cells of the memory cell blocks MCB0-MCBp are grouped into cell units CU00-CU0n through CUp0-CUpn each forming a unit column of m+1 memory cells. The m+1 memory cells of each cell unit have their drains connected together to a corresponding sub bit line (common bit line) which is among SB00-SB0n through SBp0-SBpn, and have their sources connected together to a corresponding local source line (common source line) which is among SS00-SS0n through SSp0-SSpn.

The cell units have their sub bit lines SB00-SB0n through SBp0-SBpn connected to corresponding main bit lines MB0-MBn through n-MOSFETs (N1) which are located on the drain side of cells and connected at their gates to drain-side block select signal lines MD0-MDp, and have their local source lines SS00-SS0n connected to a common source line SL through n-MOSFETs (N2) which are located on the source side of cells and connected at their gates to source-side block select signal lines MS0-MSp.

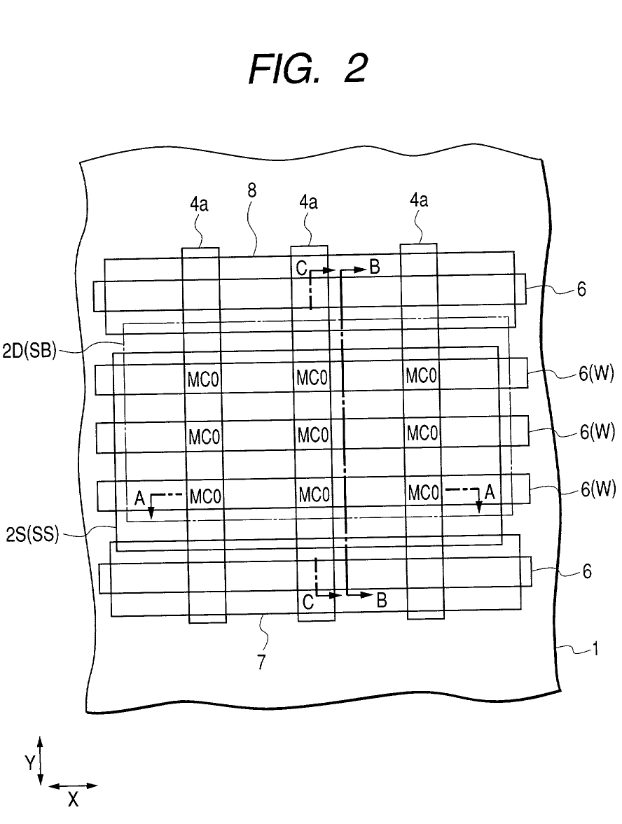

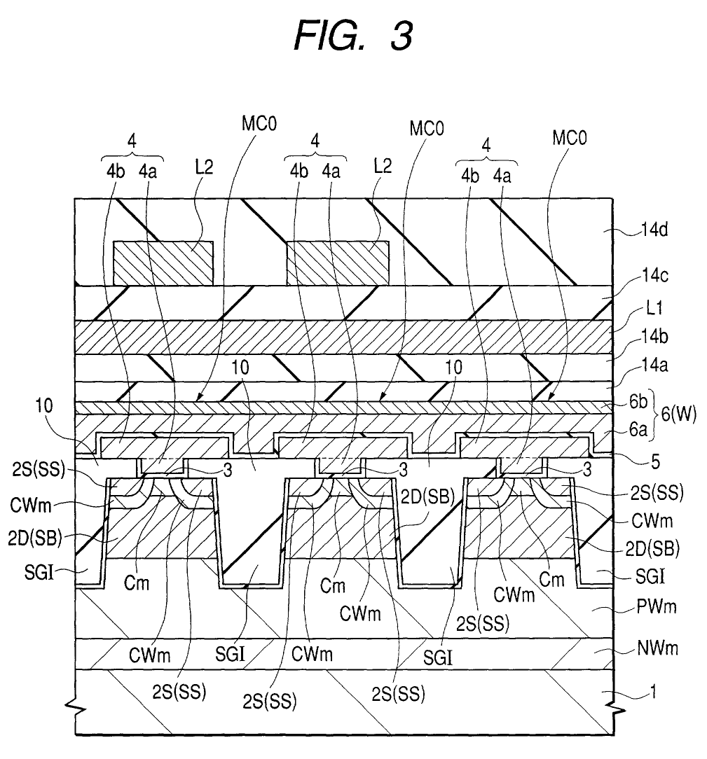

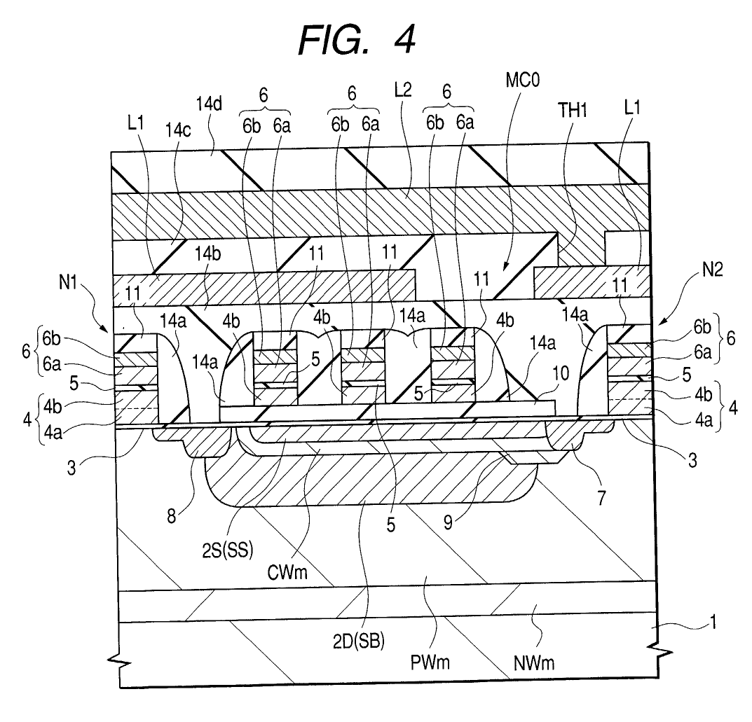

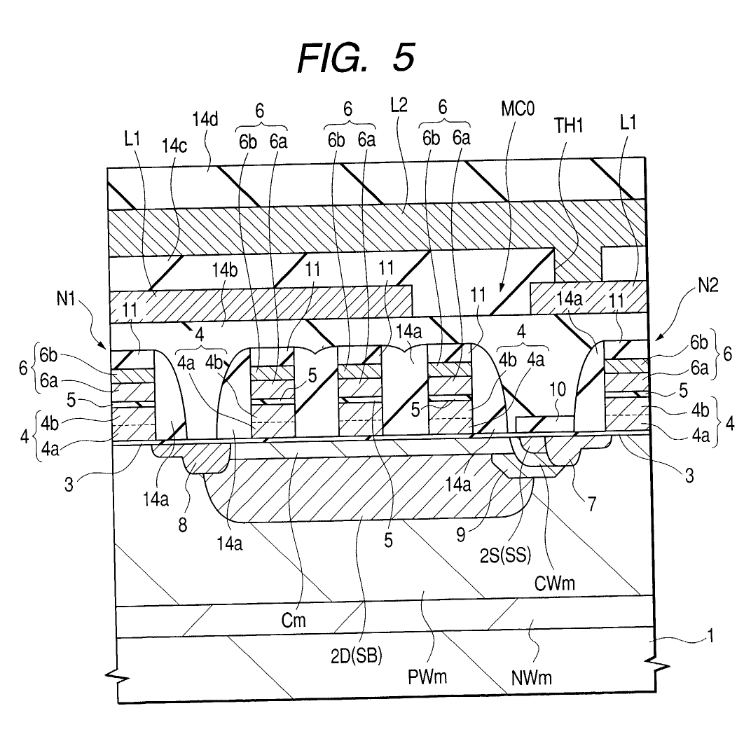

Next, the structure of memory cells MC0 of this embodiment will be explained on FIG. 2 through FIG. 5. FIG. 2 is a plan view of the memory cells MC0, FIG. 3 shows the cross section of the memory cells MC0 by cutting through the word line along its running direction (x direction in FIG. 2 ), FIG. 4 shows the cross section of the memory cells MC0 by cutting through the source section along the bit line (y direction in FIG. 2) which intersects the word line, and FIG. 5 shows the cross section of the memory cells MC0 by cutting through the channel section in the y direction. These figures show the cross-sectional structure seen in the x and y directions of memory cells for three bits.

A semiconductor substrate 1 which will become semiconductor chips is made of p-type monocrystalline silicon for example, on which a p-well PWm is formed. The p-well PWm, with boron (B) for example being implanted therein, has the formation of peripheral circuit elements including the block selecting MOSFETs N1 and N2 besides the memory cells MC0. The p-well PWm is surrounded by a buried layer of n-well NWm formed beneath it and another n-well (not shown) formed on the side of it, so that it is separated electrically from the semiconductor substrate 1. The buried n-well NWm and other n-well are formed by implanting phosphor (P) or arsenic (As), for example, into the semiconductor substrate 1, and it functions to prevent or alleviate noises of other elements on the semiconductor substrate 1 from leaking into the p-well PWm (i.e., memory cells MC0) through the substrate 1 and to establish a prescribed voltage of the p-well PWm independently of the substrate 1.

Formed on the main surface of the semiconductor substrate 1 are separation bands (trench isolation) SGI of the groove type for example. The separation band SGI is formed of an insulator film 10 which is buried in a flat-bottom groove formed in the y direction, and it functions to separate electrically individual memory cells MC0 aligning along the word line (x direction). The insulator film 10 of the separation band SGI is made of silicon oxide, etc. for example, and has its top surface flattened to be virtually parallel to the main surface of the substrate 1. The substrate 1 may also have the formation of other groove-type separation bands for separating electrically individual memory cells MC0 aligning along the bit line (y direction).

Each memory cell MC0 has n-type semiconductor regions 2S and 2D formed on the substrate 1, a gate insulation film (first insulator film) 3 formed on the main surface (active region) of the substrate 1, a conductor film 4 for the floating gate electrode (first gate electrode) formed on the film 3, an inter-layer film (second insulator film) 5 formed on the film 4, and a conductor film 6 for the control gate electrode (second gate electrode) formed on the film 5.

The n-type semiconductor regions 2S for the source regions are formed to surround a channel doped layer Cm having the p-type conductivity at two sidewise portions of the floating gate conductor film 4 on the substrate 1. The channel doped layer Cm functions to adjust the threshold voltage of the memory cell MC0. The n-type semiconductor regions 2S in pairs are surrounded by channel well regions CWm having the p-type conductivity, and the regions 2S make in unison with the channel well regions (channel formation regions) CWm a double diffusion (DD) structure.

The n-type semiconductor region 2D for the drain region is located deeper relatively to the channel well regions CWm on the substrate 1 to cover the CWm regions which are in contact with the n-type semiconductor regions 2S. Accordingly, the n-type semiconductor regions 2S for the source regions and the n-type semiconductor region 2D for the drain region are arranged by being interposed by the channel well regions CWm in the depth direction on the substrate 1.

The n-type semiconductor regions 2S are part of the local source lines SS, and the n-type semiconductor region 2D is part of the sub bit line SB. The local source lines SS and sub bit line SB are formed to extend in parallel to each other so as to have a minimum working pitch of 3F (where F is the minimum working dimension based on the design rule) along the y direction, and these planar areas are common regions of memory cells MC0 aligning in the y direction.

The local source lines SS has their one end connected to one of n-type semiconductor regions 7 for the source-drain regions of the source-side block selecting MOSFET N2, and p-type semiconductor regions 9 which are lower in concentration than the channel well regions CWm for electric field relaxation are formed below the joining section of the channel well regions CWm and n-type semiconductor regions 7. The p-type semiconductor regions 9 are depleted at writing so that the channel well regions CWm and p-well PWm are separated electrically. Forming the p-type semiconductor regions 9 enables the channel well regions CWm to have a higher impurity concentration relatively to accomplish a shorter channel region, and at the same time enables to keep the junction breakdown voltage between the sub bit line SB and p-well PWm at data writing (unselected writing). The sub bit line SB has its one end connected to one of an n-type semiconductor regions 8 for the source-drain regions of the drain-side block selecting MOSFET N1. The local source lines SS are connected electrically to the common source line SL (refer to FIG. 1) of metallic film, etc. via the block selecting MOSFET N2, and the sub bit line SB is connected electrically to the main bit line MB of metallic film, etc. via the block selecting MOSFET N1.

The gate insulation film 3 for the memory cell MC0 is a silicon oxide film, etc. having a thickness of about 9-10 nm for example, and it serves for the electron passage region (tunneling oxide film) for conducting data carrying electrons from the semiconductor substrate 1 into the conductor film 4 of floating gate electrode and releasing electrons held in the conductor film 4 to the substrate 1.

The conductor film 4 of floating gate electrode has a laminated structure of two layers (lower conductor film 4a and upper conductor film 4b ). The lower and upper conductor films 4a and 4b, which are both formed of low-resistivity polycrystalline silicon containing impurity for example, have thicknesses of about 70 nm and 40 nm, respectively, for example.

The conductor film 4 has a T-shaped cross section along the x direction by making the upper conductor film 4b wider than the lower conductor film 4a (refer to FIG. 3), enabling the conductor film 4 of floating gate electrode to confront the conductor film 6 of control gate electrode with a large area while retaining the small channel length of the memory cell MC0, and the capacitance formed between these gate electrodes can be increased. Accordingly, the memory cells MC0 even having the reduced dimensions can be improved in their operational efficiency.

The upper conductor film 4b of floating gate electrode and the substrate 1 are interposed by the insulator film 10 of silicon oxide, etc. for example, by which the upper conductor film 4b is insulated from the n-type semiconductor region pair 2S located at two sidewise portions of the floating gate electrode.

The upper conductor film 4b of floating gate electrode has its surface coated with the inter-layer film 5, by which the conductor film 4 of floating gate electrode is insulated from the conductor film 6 of control gate electrode. The inter-layer film 5 is a laminated film of silicon oxide films interposed by a silicon nitride film for example, and has a thickness of about 15 nm for example. The conductor film 6 of control gate electrode is used for data readout, writing and erasure, and it is part of the word line W. The word line W is a patterned strip extending in the channel direction, and multiple word lines are laid in parallel to have the minimum working pitch 2F. The conductor film 6 of control gate electrode (word line W) has a laminated structure of two layers (lower conductor film 6a and upper conductor film 6b) for example. The lower conductor film 6a is a low-resistivity polycrystalline silicon film of about 100 nm for example. The upper conductor film 6b is a film of tungsten silicide (WSiₓ) of about 80 nm for example, and it is laid on the lower conductor film 6a by being connected electrically. Having the upper conductor film 6b reduces the resistivity of the word line W, enabling the speed-up of the flash memory. The conductor film 6 is not confine to this structure however, but variants are possible, e.g., a laminated film of metallic films such as of tungsten interposed by a barrier conductor film such as of tungsten nitride on low-resistivity polycrystalline silicon. In this case, the word line W can have its resistivity lowered significantly, enabling the further speed-up of the flash memory. Formed on the word line W is a cap insulator film 11 of silicon oxide for example.

In this embodiment, peripheral circuit elements including the block selecting MOSFETs N1 and N2 (refer to FIG. 1 also) have virtually the same structure as the memory cells MC0 explained above. Particularly, the gate electrodes of MOSFETs N1 and N2 have a laminated structure of the conductor film 6 for control gate electrode interposed by the inter-layer film 5 on the conductor film 4 of floating gate electrode. Further detailed explanation on the structure of block selecting MOSFETs N1 and N2 is omitted.

The conductor film 4 of floating gate electrode, the conductor film 6 of control gate electrode, the gate electrodes of MOSFETs N1 and N2, and the cap insulator film 11 have their side surfaces coated with an insulator film 14a of silicon oxide for example. Particularly, the gap between adjacent word lines W running in the x direction is filled with the insulator film 14a. The insulator film 14a and conductor film 6 have upper deposition of an insulator film 14b of silicon oxide for example.

Formed on the insulator film 14b is a first-layer wiring L1 of tungsten for example. The first-layer wiring L1 is connected electrically to the n-type semiconductor region 8 of MOSFET N2 for example through a contact hall (not shown) formed in the insulator film 14b, which has upper deposition of an insulator film 14c of silicon oxide for example, by which the surface of the first-layer wiring L1 is covered. Formed on the insulator film 14c is a second-layer wiring L2, which is layers of titanium nitride, aluminum and titanium nitride laminated in this order from the bottom for example and is connected electrically to the first-layer wiring L1 through a contact hall TH1 formed in the insulator film 14c. The second-layer wiring L2 has its surface coated with an insulator film 14d of silicon oxide for example.

The memory cell MC0 of this embodiment does not need to suppress the punch-through phenomenon emerging in the channel doped layer Cm between the n-type semiconductor region pair 2S, and therefore the channel length can be made 0.1 μm or less. Even with the channel length of 0.1 μm or less, the n-type semiconductor region pair 2S of source region and the n-type semiconductor region 2D of drain region are laid in the depth direction in the substrate 1 by being interposed by the channel well regions CWm, and it is possible to keep a source-to-drain breakdown voltage (punch-through breakdown voltage) of 1 V or higher (e.g. about 3 V) based on the DD structure of the n-type semiconductor regions 2S and channel well regions CWm and the provision of a certain spacing between the n-type semiconductor regions 2S and 2D.

By forming the n-type semiconductor region 2D to cover the channel well regions CWm, the regions CWm which are in contact with the n-type semiconductor regions 2S can be separated from the comm on p-well PWm. By designing the channel well regions CWm and p-well PWm to have different impurity concentrations so that the junction breakdown voltage between the n-type semiconductor region 2D and the p-well PWm can be set higher than the source-to-drain punch-through breakdown voltage, it becomes possible to have a junction breakdown voltage between the region 2D and the p-well PWm of 6 V or higher.

Providing the channel doped layer Cm facilitates the adjustment of the threshold voltage and also lets the current between the n-type semiconductor region pair 2S flow deep from the surface of substrate 1, casing hot electrons to be precluded from entering into the gate insulator film 3, and it becomes possible to prevent the decay of gate insulator film 3 and the fluctuation of threshold voltage.

The n-type semiconductor region 2D which is part of the sub bit line SB is formed deep in the substrate 1 so that it can have the setting of an intended impurity concentration independently of the source regions without being dependent on the channel length for example, and it becomes possible to lower the resistivity relatively.

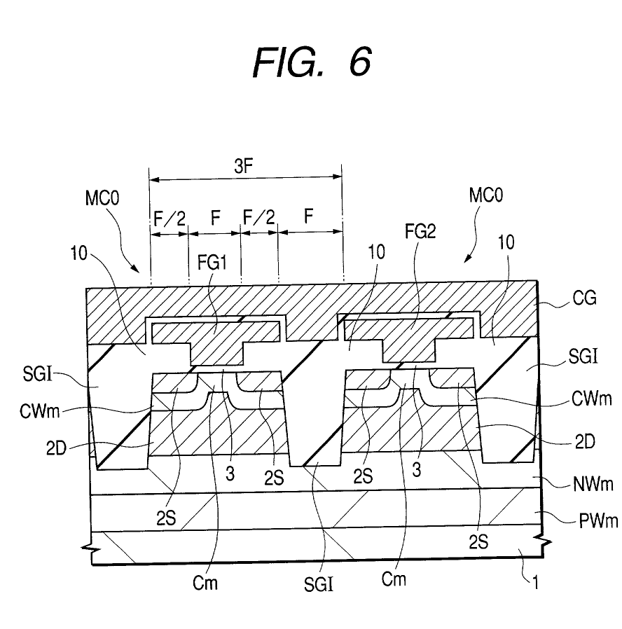

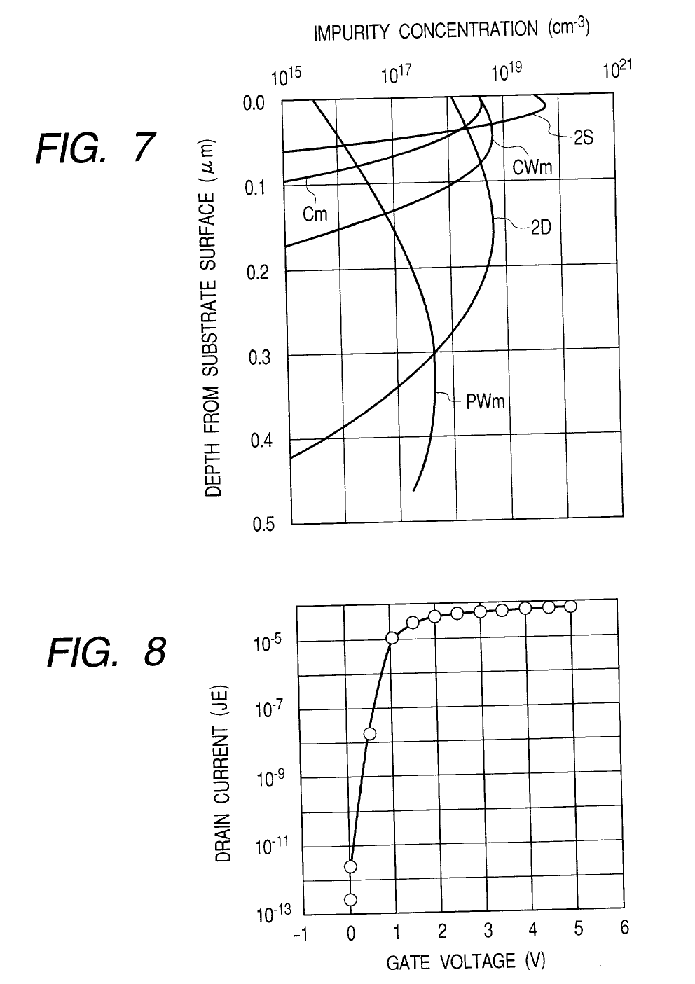

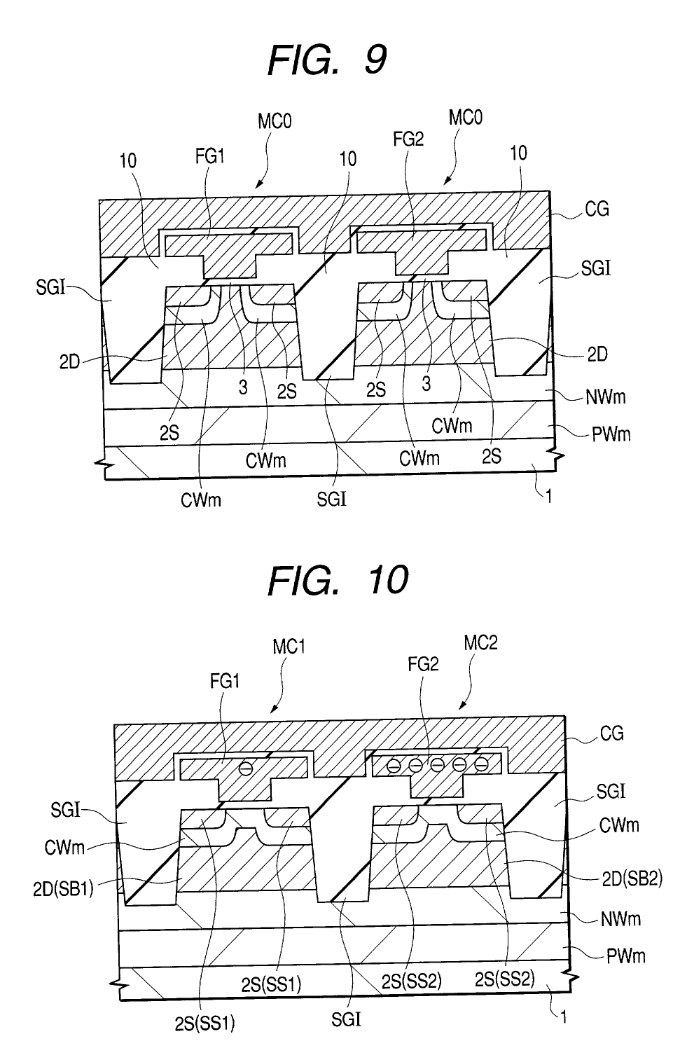

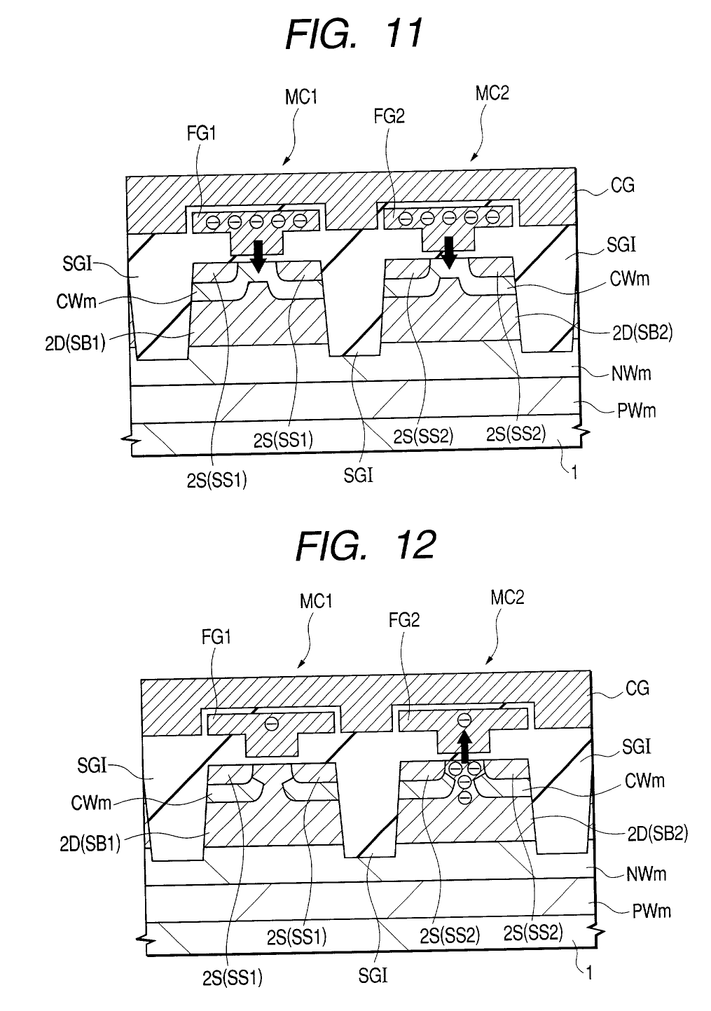

Next, an example of the structure and the operation of the memory cell of this embodiment will be explained with reference to FIG. 6 through FIG. 12. FIG. 6 shows an example of the cross section of the memory cell, FIG. 7 shows the concentration profiles of the semiconductor regions formed on the semiconductor substrate, FIG. 8 shows by graph the drain current vs. gate voltage relation of the memory cell shown in FIG. 6, FIG. 9 shows a variant example of the cross section of the memory cell, FIG. 10 shows the cross section of the memory cell explaining the data readout operation, FIG. 11 shows the cross section of the memory cell explaining the data erase operation, and FIG. 12 shows the cross section of the memory cell explaining the data write operation. Shown in FIG. 6 and FIG. 9 through FIG. 12 is the cross-sectional structure of memory cells for two bits aligning in the channel direction.

FIG. 6 is a brief cross-sectional diagram showing an example of memory cells MC0 having a bit line pitch of 3F, where F is the minimum working dimension. Specifically, the lower conductor film, which is formed on the channel doped layer Cm through the gate insulation film 3 to constitute part of a floating gate electrode FG1 (FG2), has a width in the channel direction equal to the minimum working dimension F, the upper conductor film, which is formed on the n-type semiconductor regions 2S for the source region through the insulator film 10 to constitute the rest of the floating gate electrode FG1 (FG2), has a width in the channel direction equal to half the minimum working dimension F, and the separation band SGI has a width in the channel direction equal to the minimum working dimension F.

FIG. 7 shows an example of the distributions of impurity concentration of the n-type semiconductor regions 2S for the source region, the channel doped layer Cm, the channel well region CWm, the n-type semiconductor region 2D for the drain region, and the p-well PWm. The n-type semiconductor regions 2S for the source region is made of arsenic for example, and the channel doped layer Cm and channel well region CWm are made of boron for example. The n-type semiconductor region 2D for the drain region is made of phosphor for example, or may be of other n-type impurity, e.g., arsenic.

By setting a peak concentration of 10¹⁸ cm⁻³ or higher for example for the channel well region CWm, it is possible to provide a source-drain punch-through breakdown voltage of 1 V or higher for the data read operation. By setting an impurity concentration of 1×10¹⁷ cm⁻³ or higher for example for the n-type semiconductor region 2D and p-well PWm, it is possible to provide a 2D-PWm junction breakdown voltage of 6 V or higher for the data write operation.

FIG. 8 shows an example of the drain current vs. gate voltage relation of the memory cell MO shown in FIG. 6. A drain current of 1 μA can produce a gate voltage (threshold voltage) of about 0.8 V.

FIG. 9 is a brief cross-sectional diagram showing a variant example of the memory cell MC0 having a bit line pitch of 3F. As in the case of the memory cell explained on FIG. 6, the channel well regions CWm which are in contact with the n-type semiconductor region pair 2S for the source region are covered by the n-type semiconductor region 2D for the drain region, and the p-well PWm is formed beneath the region 2D. However, the channel doped layer Cm is absent at the portion of the semiconductor substrate 1 which is in contact with the gate insulation film 3 of tunneling oxide film, but the n-type semiconductor region 2D is formed in this place.

Next, the data readout operation of the memory cells MC1 and MC2 will be explained on FIG. 10.

The memory cell MC1 does not have electrons injected into its floating gate electrode FG1, and it stores data of “1”. The memory cell MC2 has electrons injected into its floating gate electrode FG2, and it stores data of “0”. Data readout takes place for each word line. The selected word line (control gate electrode CG) has the application of a positive voltage, e.g.,3 V, and unselected word lines have the application of 0 V for example. The local source lines SS1 and SS2 (n-type semiconductor regions 2S), channel well region CWm and p-well PWm have the application of 0 V for example, and the sub bit lines SB1 and SB2 (n-type semiconductor regions 2D) have the application of 1 V for example. The memory cell MC1 having a low threshold voltage has its bit line voltage falling, while the memory cell MC2 having a high threshold voltage has its bit line voltage retained at about 1 V, and accordingly data of the memory cells MC1 and MC2 can be read out by detecting the voltage of the respective bit lines.

Next, the data erase operation of the memory cells MC1 and MC2 will be explained on FIG. 11. Data erasing takes place for each word line, with the memory cells MC1 and MC2 being erased simultaneously. A selected word line (control gate electrode CG) has the application of a negative voltage, e.g., −16 V. The local source lines SS1 and SS2 (n-type semiconductor regions 2S), sub bit lines SB1 and SB2 (n-type semiconductor regions 2D), channel well regions CWm, and p-well PWm have the application of 0 V for example. With this voltage condition being set, the memory cells MC1 and MC2 have their tunneling oxide film subjected to a strong electric field on the entire surface, causing the floating gate electrodes FG1 and FG2 to release electrons to the channel regions, and the threshold voltage is set lower relatively.

Next, the data write operation of the memory cells MC1 and MC2 will be explained on FIG. 12. Data writing takes place for each word line. The selected word line (control gate electrode CG) has the application of a positive voltage, e.g., 18 V, and unselected word lines have the application of 0 V for example. The local source line SS2 (n-type semiconductor regions 2S) of the memory cell MC2 which undergoes selective writing of “0” is left open, while the channel well region CWm and p-well PWm have the application of 0 V for example. In consequence, an n-type inverted layer is created in the channel region, causing the n-type semiconductor region pair 2S and n-type semiconductor region 2D to be linked to have the same potential, and the electric field on the tunneling oxide film increases to inject electrons into the floating gate electrode FG2 through the entire surface of the tunneling oxide film. Accordingly, the threshold voltage is set higher relatively, and data of “0” is written.

The local source line SS1 (n-type semiconductor regions 2S) of the memory cell MC1 which undergoes selective writing of “1” is left open, while the sub bit line SB2 (n-type semiconductor region 2D) have the application of a positive voltage, e.g.,6 V, and the channel well region CWm and p-well PWm have the application of 0 V for example. In consequence, an n-type inverted layer is created in the channel region, causing the n-type semiconductor region pair 2S and n-type semiconductor region 2D to be linked. However, the electric field on the tunneling oxide film of the memory cell MC1, which is weaker relative to that of the memory cell MC2, scarcely injects electrons into the floating gate electrode FG1. Accordingly, the threshold voltage is set lower relatively, and data of “0” is written (i.e., data is erased).

The following Table 1 lists the operational voltages of the foregoing data readout operation, erase operation and write operation.

TABLE 1

| | | selected- | unselected- | |
|---|---|---|---|---|
| | readout | write | write | erase |
| word line | 3 V | 18 V | 18 V | −16 V |
| drain | 1 V | 0 V | 6 V | 0 V |
| source | 0 V | Open | Open | 0 V |
| well | 0 V | 0 V | 0 V | 0 V |
| substrate | 0 V | 0 V | 0 V | 0 V |

The example of operational voltages shown in this table is of the 2-level storing scheme in which one memory cell can store two levels of “0” and “1”, while the inventive device can also be applied to multi-level storing scheme in which one memory cell can store multiple levels, e.g., the 4-value storing scheme for “11”, “10”, “00” and “11”. The following Table 2 lists an example of the operational voltages of this case.

TABLE 2

| | | | selected- | | unselected- | |
|---|---|---|---|---|---|---|
| | readout | | write | | write | erase |
| word line | 2, 3, 4 | V | 16, 17, 18 | V | 18 V | −16 V |
| drain | 1 | V | 0 | V | 6 V | 0 V |
| source | 0 | V | Open | | Open | 0 V |
| well | 0 | V | 0 | V | 0 V | 0 V |
| substrate | 0 | V | 0 | V | 0 V | 0 V |

Next, an example of the method of fabricating the flash memory of the first embodiment will be explained on a step-by-step basis.

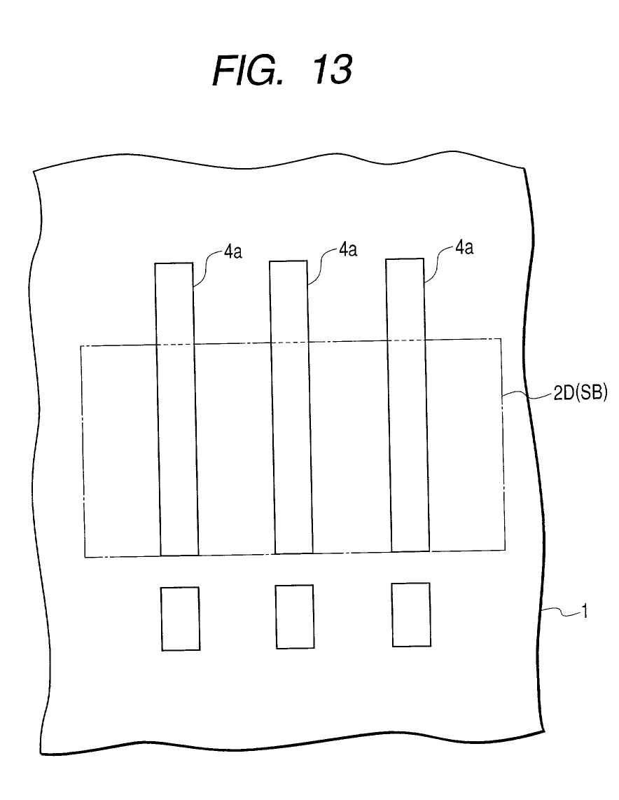

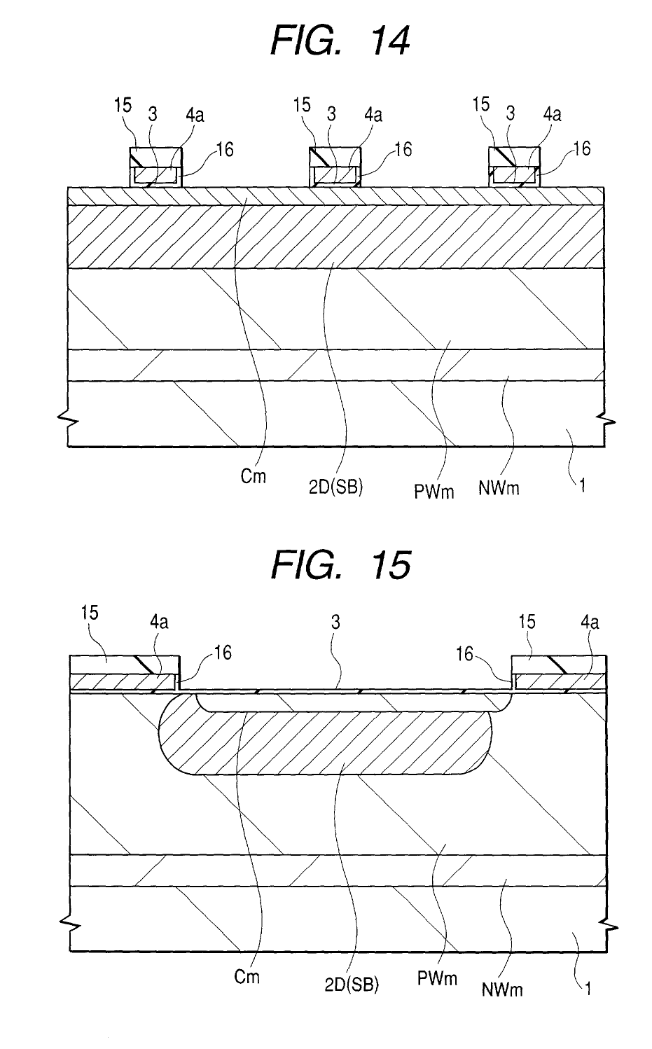

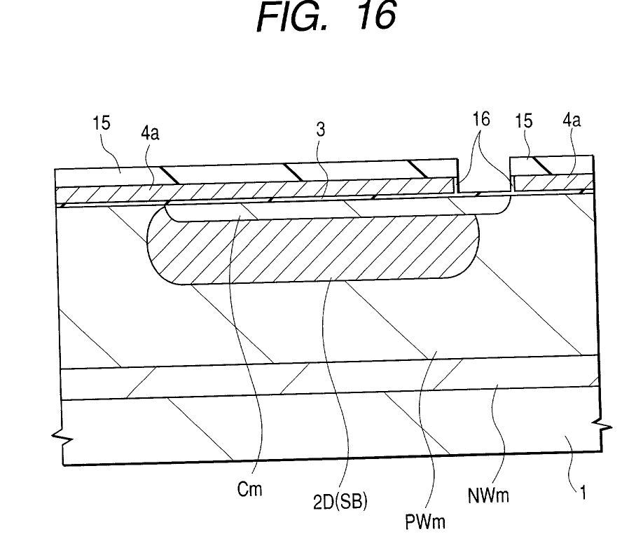

FIG. 13 through FIG. 16 show the flash memory at the fabrication steps. FIG. 13 shows by plan view the principal portion of the device comparable with FIG. 2, FIG. 14 shows the cross section of the memory array of flash memory by cutting through the word line along its running direction (comparable with the A-A cross section of FIG. 2), FIG. 15 shows the cross section of a memory cell by cutting through the source section in the direction which intersects the word line (comparable with the B-B cross section of FIG. 2), and FIG. 16 shows the cross section of the memory cell by cutting through the channel section along the local source line running direction (comparable with the C-C cross section of FIG. 2).

Initially, prescribed impurity is implanted selectively into certain portions of a semiconductor substrate 1 (a wafer which is a semiconductor disc) by the ion implanting process or the like at a prescribed energy, thereby forming a buried n-well NWm, p-well PWm, n-type semiconductor region 2D (sub bit line SB), and channel doped layer Cm. The n-type semiconductor region 2D is formed by implanting phosphor ion by a dose of 1×10¹⁴ cm⁻² at an energy level of 150 keV for example, and the channel doped layer Cm is formed by implanting boron ion by a dose of 5×10¹³ cm⁻² at an energy level of 20 keV for example. Subsequently, the semiconductor substrate 1 is treated by the thermal oxidation process thereby to form a tunneling oxide film for the memory array. Consequently, a gate insulation film 3 of about 9 nm in thickness is formed on the substrate surface of the memory array.

Next, a lower conductor film 4a of low-resistivity polycrystalline silicon having a thickness of about 70 nm for example and an insulator film 15 of silicon nitride, etc. having a thickness of about 140 nm for example are deposited sequentially on the main surf ace of the semiconductor substrate 1 by the CVD process or the like, and thereafter the insulator film 15 and lower conductor film 4a are worked by the photolithographic process and dry etching process, thereby patterning the film 4a to form the floating gate electrodes of the memory array. During these processes, the peripheral circuit regions (selecting MOSFET regions, etc.) are covered generally by the lower conductor film 4a and insulator film 15. Subsequently, the semiconductor substrate 1 is treated by the thermal oxidation process so that another insulator film 16 of silicon oxide which is thinner relatively is formed on the surface of the lower conductor film 4a.

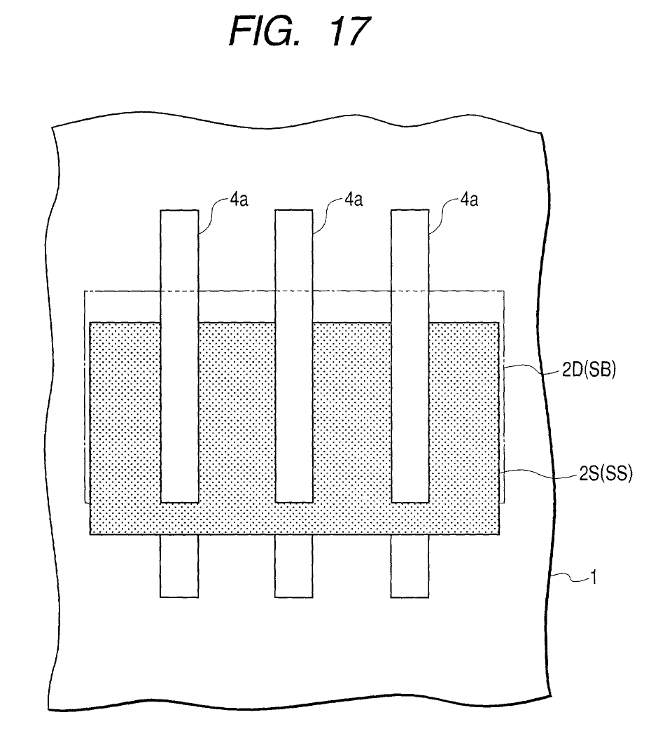

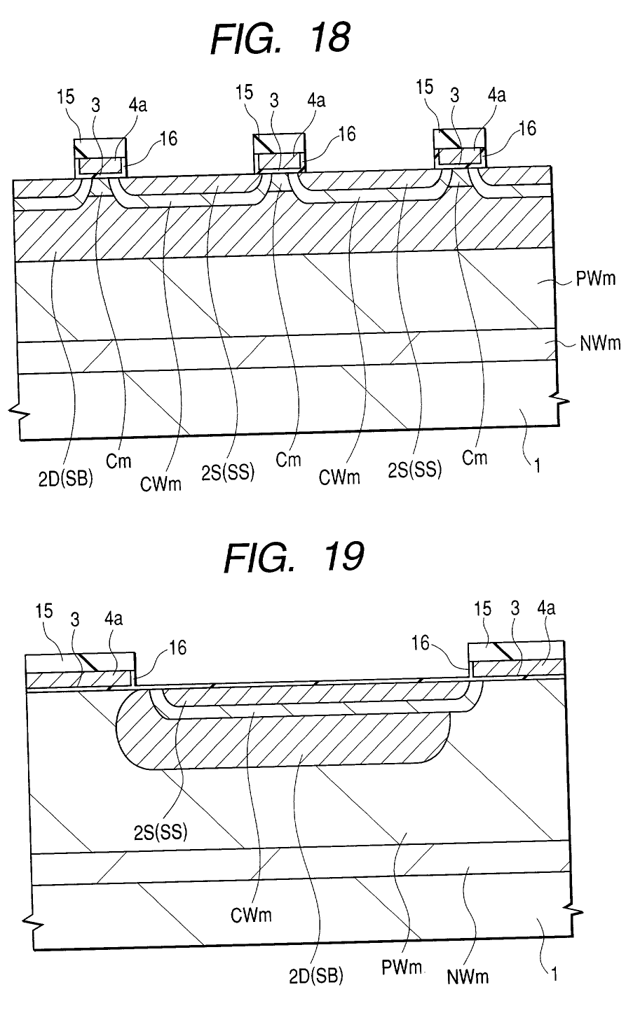

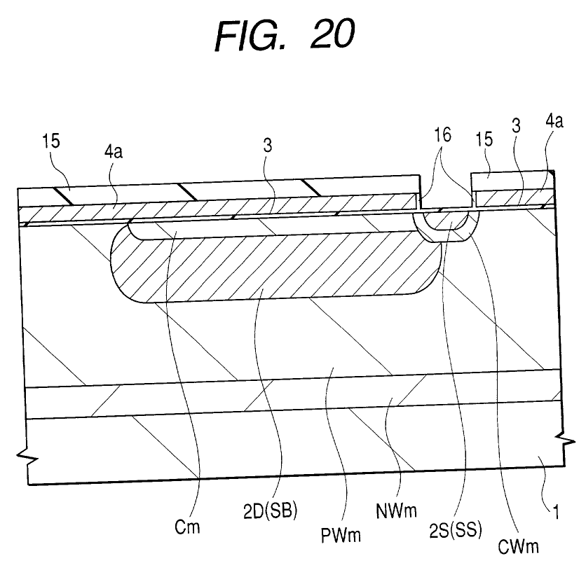

FIG. 17 shows by plan view the same principal portion as FIG. 13 at the subsequent fabrication step, FIG. 18 shows the same cross section as FIG. 14 at the subsequent fabrication step, FIG. 19 shows the same cross section as FIG. 15 at the subsequent fabrication step, and FIG. 20 shows the same cross section as FIG. 16 at the subsequent fabrication step.

Initially, impurity (e.g., boron) for the channel well regions CWm is implanted into the semiconductor substrate 1 by the ion implanting process or the like. Subsequently, impurity (e.g., arsenic) for the source of memory cell is implanted into the semiconductor substrate 1 by the ion implanting process or the like, thereby forming a pair of n-type semiconductor regions 2S (local source lines SS) having a surface concentration of 1×10¹⁹ cm⁻³ or more. The channel well regions CWm are formed by implanting boron ion by a dose of 2×10^{13 cm}⁻² at an energy level of 10 keV for example, and the n-type semiconductor regions 2S are formed by implanting arsenic ion by a dose of 5×10¹⁴ cm⁻² at an energy level of 30 keV for example. The junction between the regions 2S and the regions CWm has its impurity concentration set to be about 1×10¹⁸ cm⁻³.

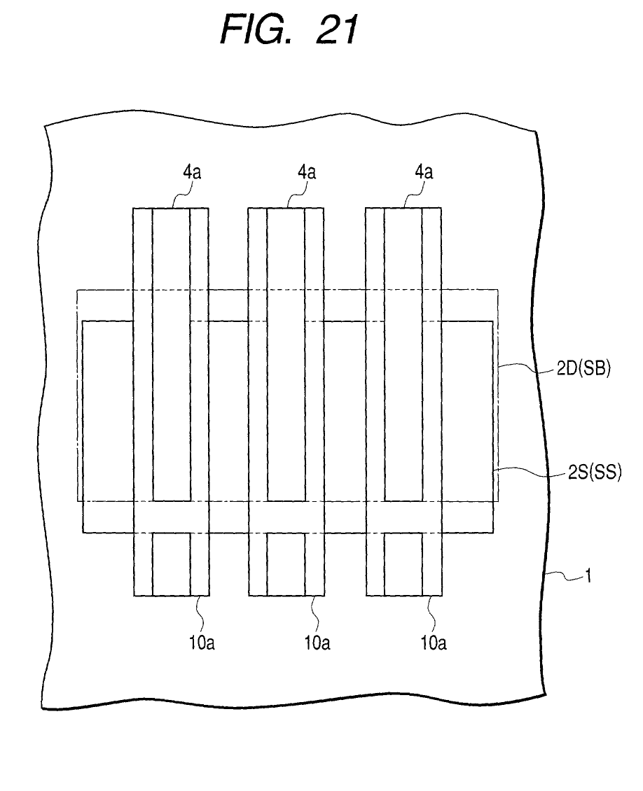

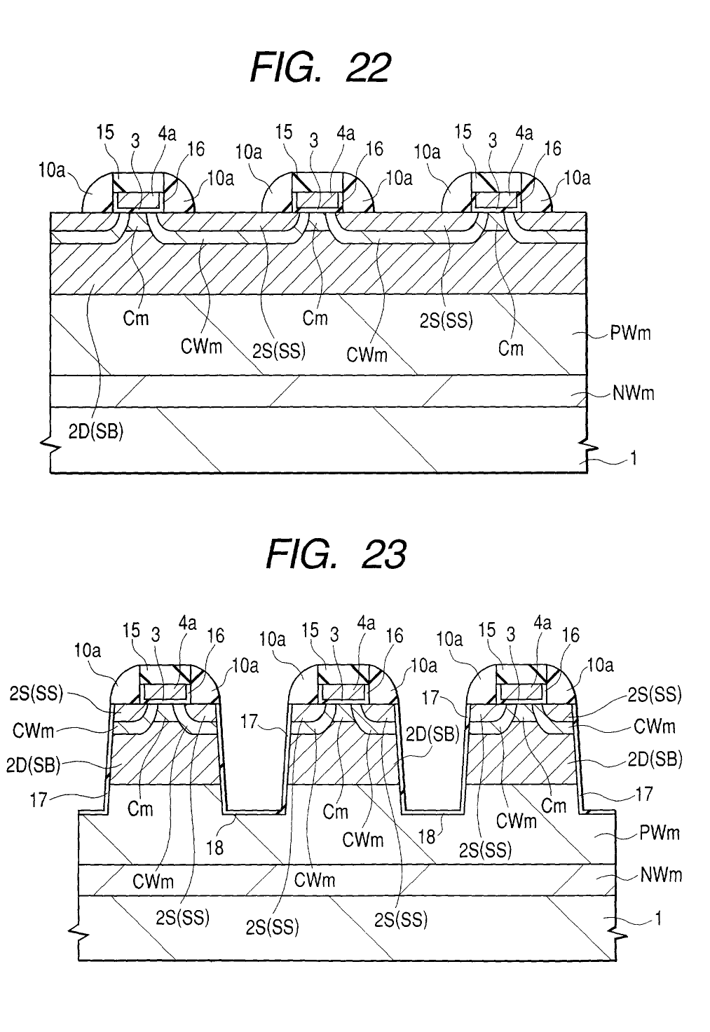

FIG. 21 shows by plan view the same principal portion as FIG. 13 at the subsequent fabrication step, and FIG. 22 shows the same cross section as FIG. 14 at the subsequent fabrication step.

An insulator film (third insulator film) 10a of silicon oxide for example is deposited on the main surface of the semiconductor substrate 1 by the CVD process or the like, and thereafter it is worked by anisotropic etching of the reactive ion etching (RIE) process or the like so as to leave the insulator film 15 and insulator film 10a on the side wall of the lower conductor film 4a.

FIG. 23 shows the same cross section as FIG. 14 at the subsequent fabrication step.

The semiconductor substrate 1 is etched by using the insulator film 15, the lower conductor film 4a for floating gate electrode and the insulator film 10a as a mask, thereby forming separation groove 17 in auto-matching fashion in the semiconductor substrate 1. Although the bit line pitch is set to be 3F in this embodiment, which is derived from the width of n-type semiconductor region 2S (local source line SS) in the channel direction and the width of separation groove 17 both determined in this process, it is possible to set the bit line pitch smaller than 3F by reducing the widths of the region 2S and groove 17 while leaving the minimum working dimension F unchanged. Subsequently, the semiconductor substrate 1 is treated by the low-temperature thermal oxidation process so that an insulator film 18 of silicon oxide which is thinner relatively is formed on the surface of the separation groove 17. The insulator film 18 functions to block the leak current.

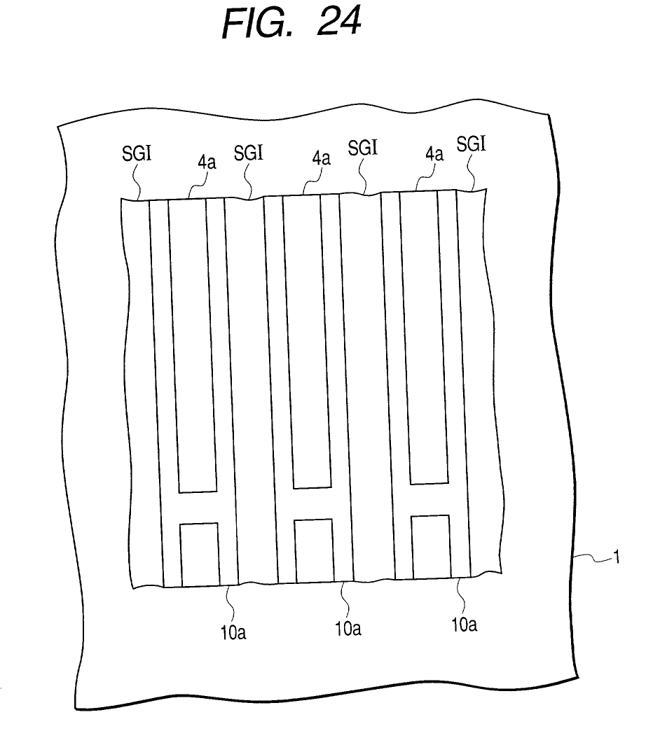

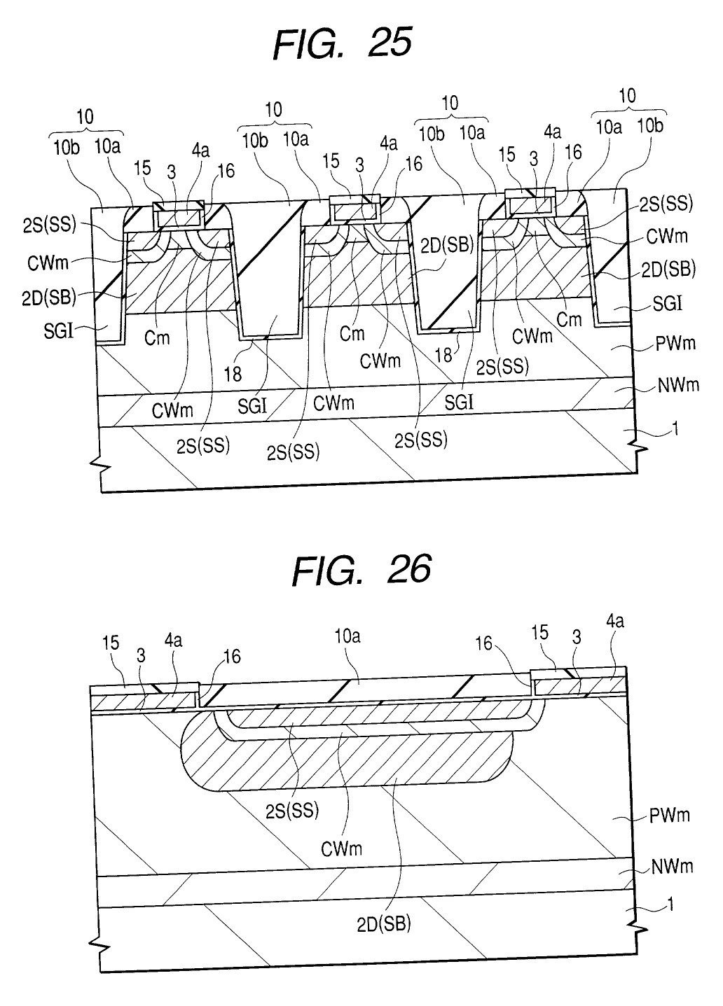

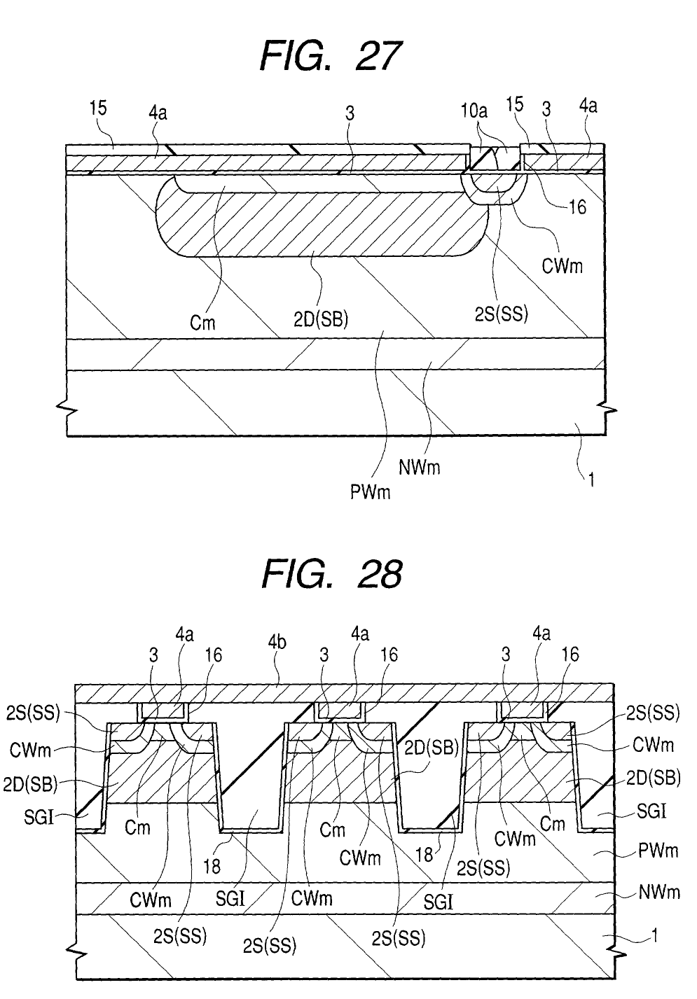

FIG. 24 shows by plan view the same principal portion as FIG. 13 at the subsequent fabrication step, FIG. 25 shows the same cross section as FIG. 14 at the subsequent fabrication step, FIG. 26 shows the same cross section as FIG. 15 at the subsequent fabrication step, and FIG. 27 shows the same cross section as FIG. 16 at the subsequent fabrication step.

An insulator film of silicon oxide for example is deposited on the main surface of the semiconductor substrate 1, and next the insulator film is abraded while being left in the separation groove 17 and the recesses on the main surface of the semiconductor substrate 1 by the chemical-mechanical polishing (CMP) process or the like, resulting in the formation of the separation band SGI. The periphery of the conductor film 4a for the floating gate electrode is filled with the insulator films 10 (insulator film 10a and insulator film 10b (fourth insulator film)).

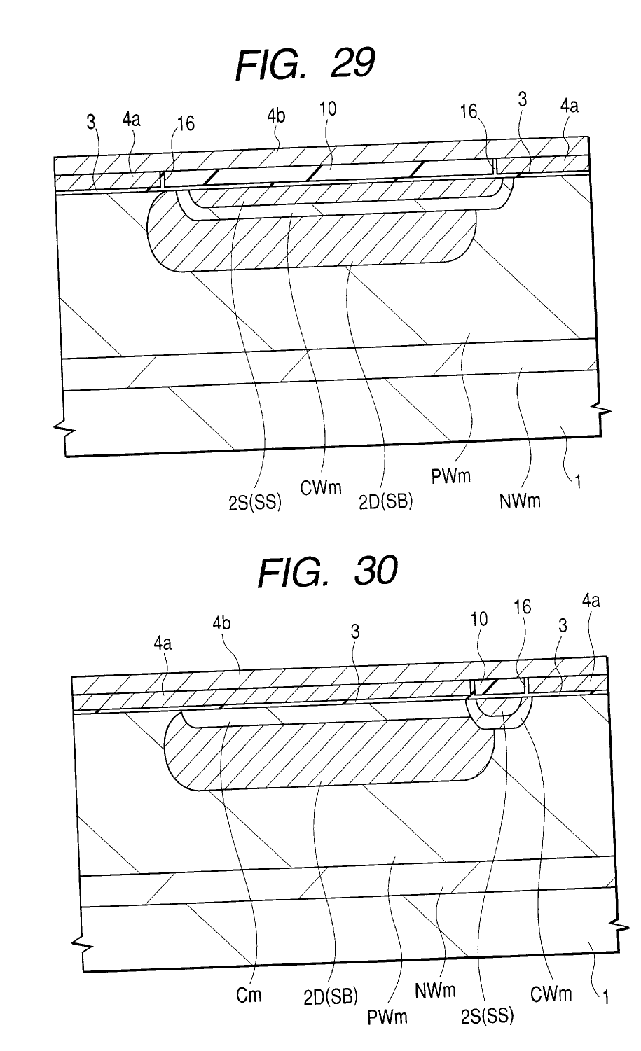

FIG. 28 shows the same cross section as FIG. 14 at the subsequent fabrication step, FIG. 29 shows the same cross section as FIG. 15 at the subsequent fabrication step, and FIG. 30 shows the same cross section as FIG. 16 at the subsequent fabrication step.

The insulator film 15 is removed by the thermal phosphating process or the like, and thereafter an upper conductor film 4b of low-resistivity polycrystalline silicon is formed to have a thickness of about 40 nm for example on the main surface of the semiconductor substrate 1.

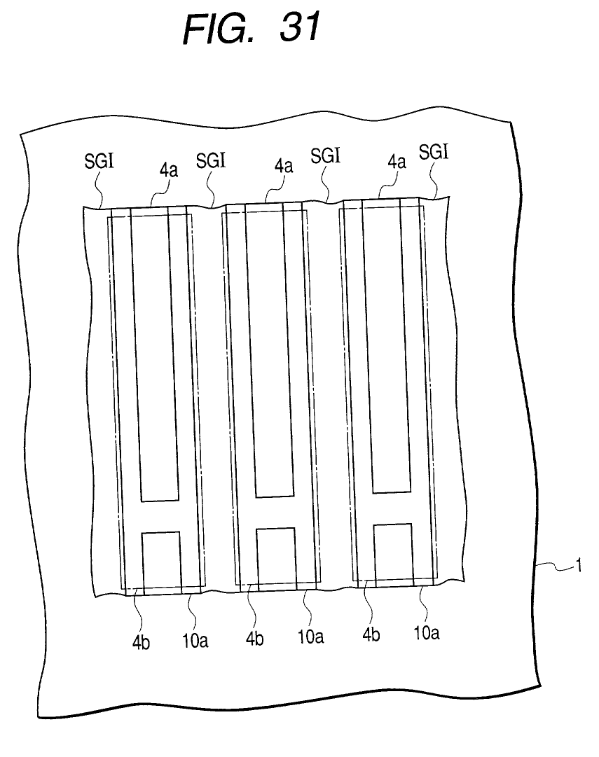

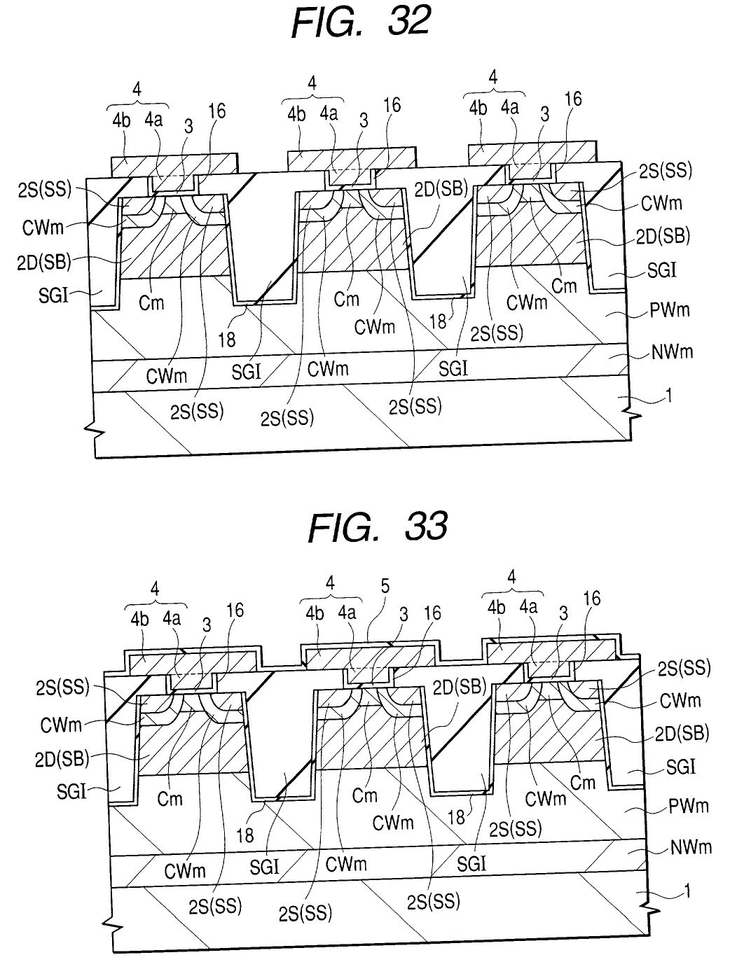

FIG. 31 shows by plan view the same principal portion as FIG. 13 at the subsequent fabrication step, and FIG. 32 shows the same cross section as FIG. 14 at the subsequent fabrication step.

The upper conductor film 4b is etched off by using a mask of a photoresist pattern which is formed on it by the photolithographic process, thereby forming a floating gate electrode consisting of a lower conductor film 4a and upper conductor film 4b.

FIG. 33 shows the same cross section as FIG. 14 at the subsequent fabrication step.

A silicon oxide film, silicon nitride film and silicon oxide film, for example, are deposited in this order from the bottom on the semiconductor substrate 1 by the CVD process or the like, thereby forming an inter-layer film 5 having a thickness of about 15 nm for example.

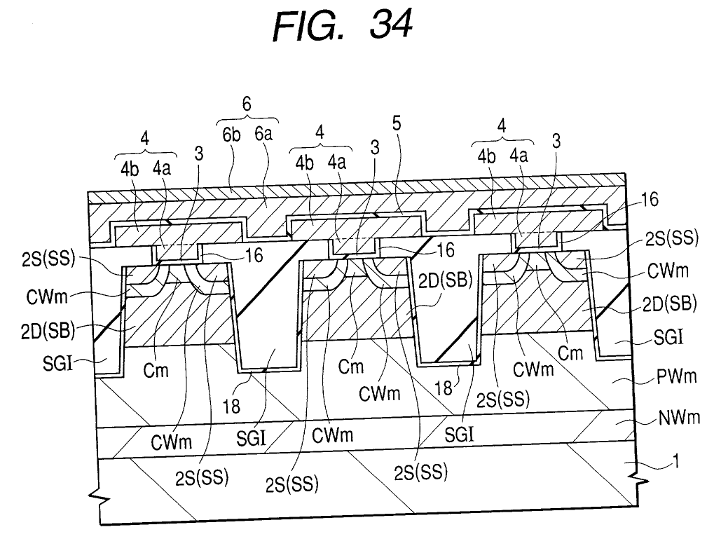

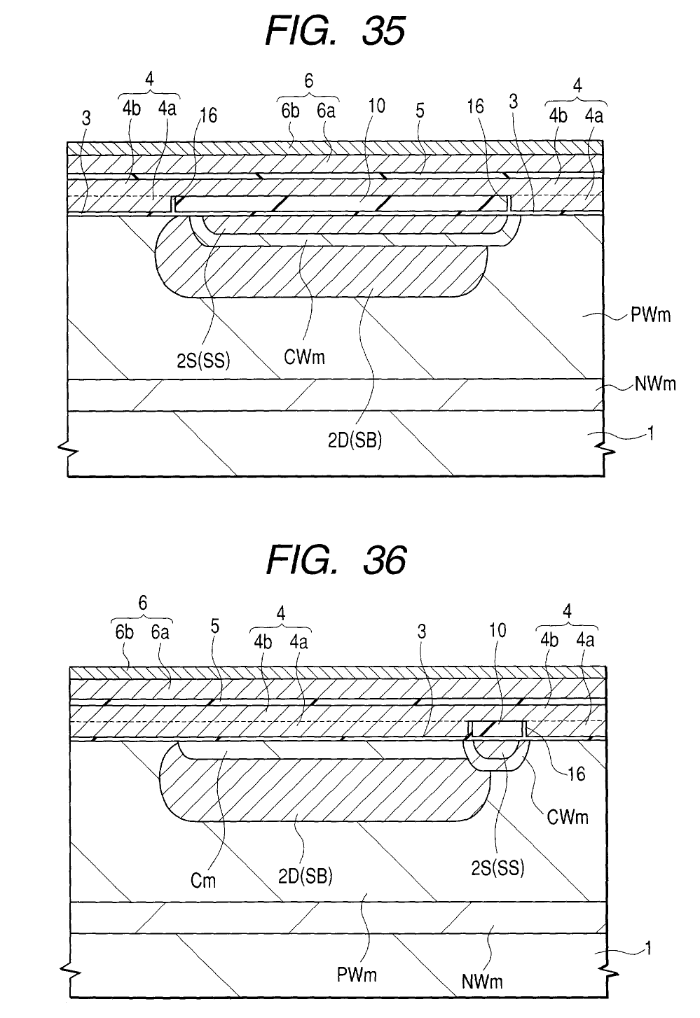

FIG. 34 shows the same cross section as FIG. 14 at the subsequent fabrication step, FIG. 35 shows the same cross section as FIG. 15 at the subsequent fabrication step, and FIG. 36 shows the same cross section as FIG. 16 at the subsequent fabrication step.

A lower conductor film 6a of low-resistivity polycrystalline silicon for example and an upper conductor film 6b of tungsten silicide for example are deposited sequentially on the semiconductor substrate 1 by the CVD process or the like.

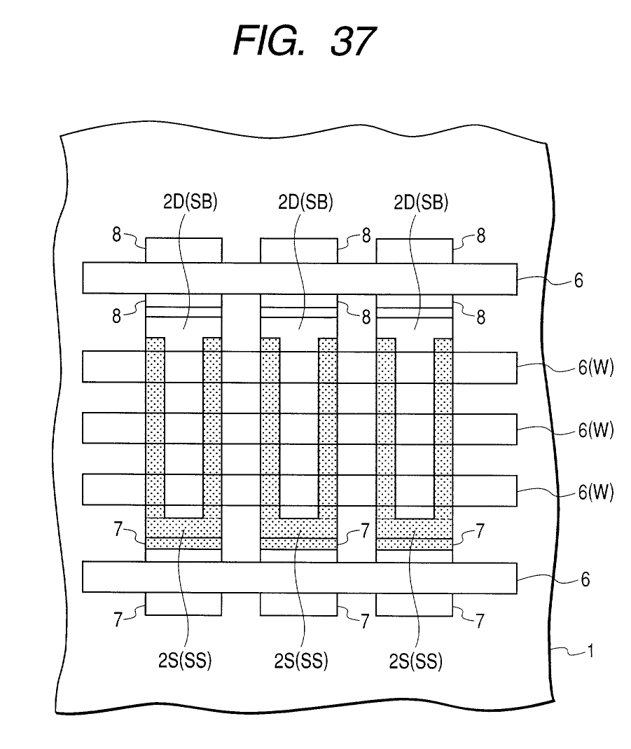

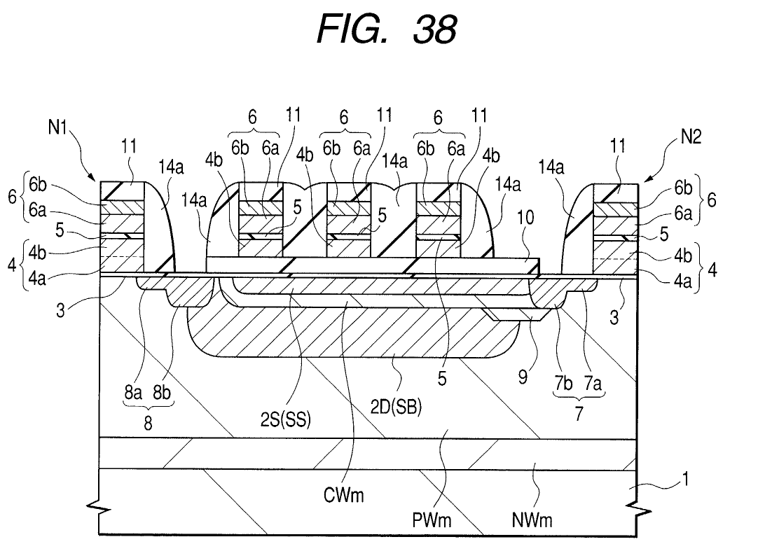

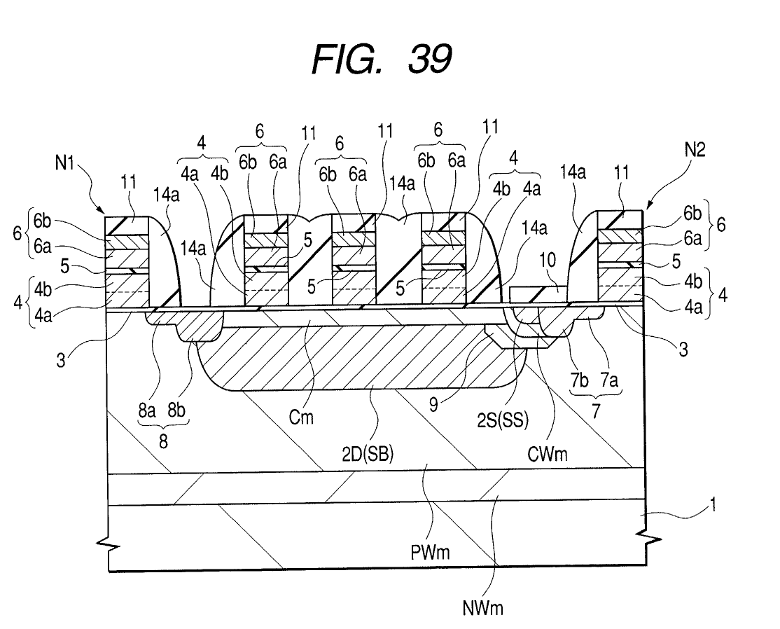

FIG. 37 shows by plan view the same principal portion as FIG. 13 at the subsequent fabrication step, FIG. 38 shows the same cross section as FIG. 15 at the subsequent fabrication step, and FIG. 39 shows the same cross section as FIG. 16 at the subsequent fabrication step.

A cap insulator film 11 is deposited on the upper conductor film 6b, and thereafter the film 11 and the upper and lower conductor films 6b and 6a are etched off by the dry etching process or the like by using a mask of a photoresist pattern which is formed on it by the photolithographic process, thereby forming control gate electrodes (word lines W) for the memory array and forming part of gate electrodes of MOSFETs for other regions, e.g., region of block selecting MOSFETs. During this etching process, the inter-layer film 5 is used to function as etching stopper. Subsequently, the lower inter-layer film 5 and the upper and lower conductor films 6b and 6a are etched off by the dry etching process or the like by using the cap insulator film 11 and conductor films 6 as etching stopper.

For the memory array, the control gate electrodes and floating gate electrodes of the memory cell are now completed. This is the double-layer-gate electrode structure including the conductor film 6 for the control gate electrode laminated on the conductor film 4 for the floating gate electrode by being interposed by the inter-layer film 5. The floating gate electrode and the control gate electrode of the memory cell are insulated completely from each other. For the peripheral circuit region, gate electrodes of the block selecting MOSFETs N1 and N2, for example, are completed.

Next, semiconductor regions 7a and 8a having an impurity concentration which is lower relatively are formed for the block selecting MOSFETs N1 and N2. These regions 7a and 8a have the implantation of arsenic for example. Subsequently, an insulator film of silicon oxide for example is deposited on the main surface of the semiconductor substrate 1 by the CVD process or the like, and thereafter it is etched back by the anisotropic dry etching process or the like, thereby forming an insulator film 14a on the side surface of the gate electrodes of the MOSFETs N1 and N2. The insulator film 14a is used at the same time to fill the gap between adjacent word lines W.

Next, semiconductor regions 7b and 8b having an impurity concentration which is higher relatively are formed for the block selecting MOSFETs N1 and N2. These regions 7a and 8a have the implantation of arsenic for example. A pair of n-type semiconductor regions 7 and 8 for the sources and drains of the block selecting MOSFETs N1 and N2 are now formed. The n-type semiconductor region 8 of the drain-side MOSFET N1 and the sub bit line SB (n-type semiconductor region 2D) are connected, and the n-type semiconductor regions 7 of the source-side MOSFET N2 and the local source lines SS (n-type semiconductor regions 2S) are connected. In addition, a p-type semiconductor region 9, which works for electric field relaxation, is formed beneath the junction of the n-type semiconductor region 7b of the source-side MOSFET N2 and the channel well region CWm.

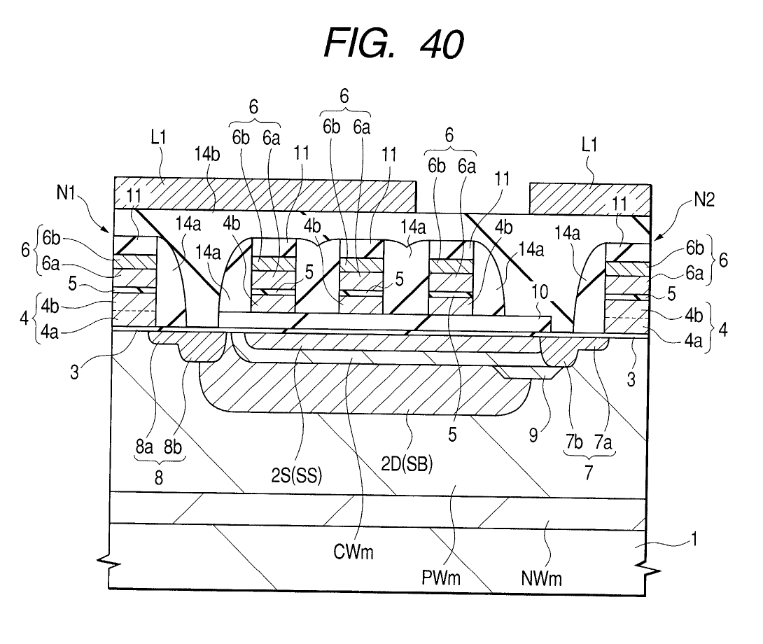

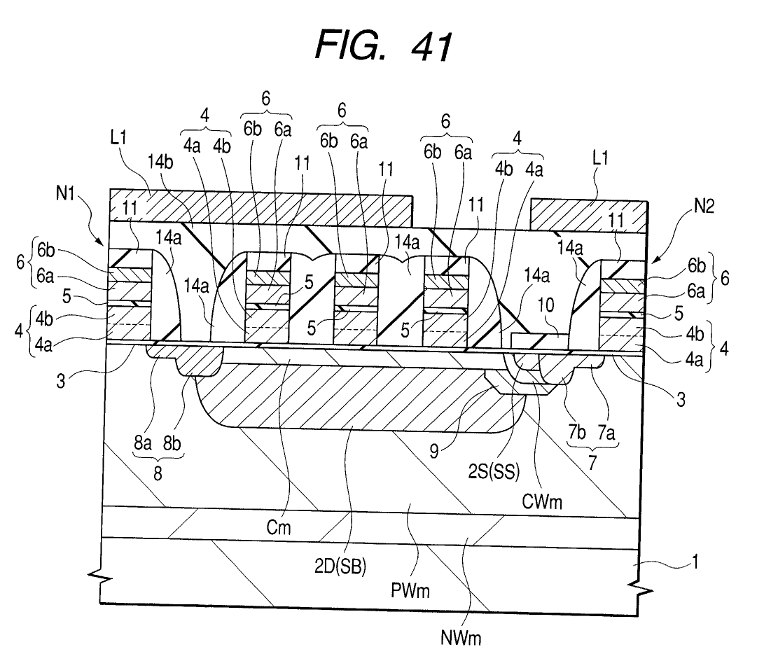

FIG. 40 shows the same cross section as FIG. 15 at the subsequent fabrication step, and FIG. 41 shows the same cross section as FIG. 16 at the subsequent fabrication step.

An insulator film 14b of silicon oxide for example is deposited on the semiconductor substrate 1 by the CVD process or the like, and thereafter it is treated by the photolithographic process and dry etching process to make contact halls so as to expose part of the semiconductor substrate 1 (source-drain regions of MOSFETs), part of the word line, and part of the gate electrode of certain MOSFETs. Subsequently, a metallic film of tungsten for example is deposited on the semiconductor substrate 1 by the sputtering process or the like, and thereafter it is patterned by the photolithographic process and dry etching process, thereby forming first-layer wirings L1 (including the common source line). The first wirings L1 are connected electrically through the contact halls to the semiconductor region pair for the sources and drains of MOSFETs, gate electrodes, and word lines.

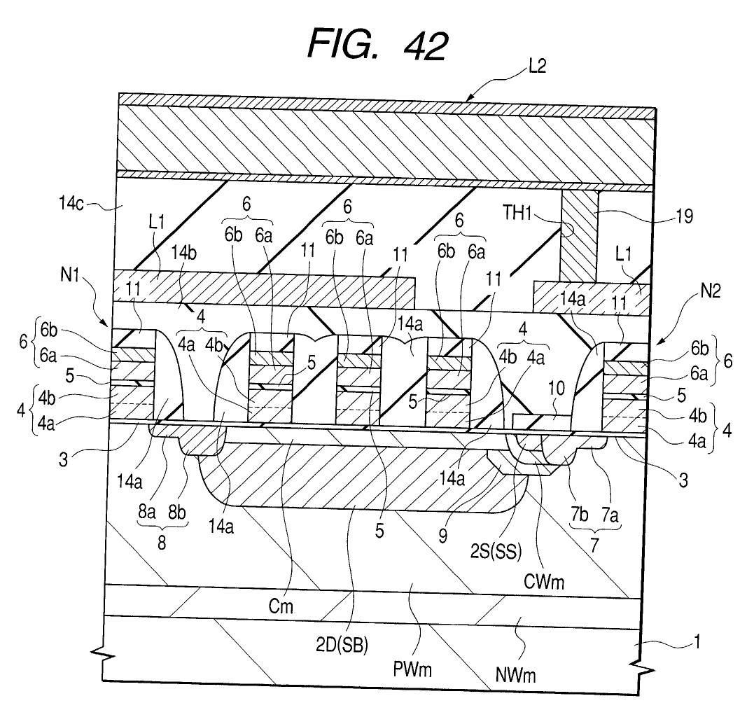

FIG. 42 shows the same cross section as FIG. 16 at the subsequent fabrication step.

An insulator film 14c of silicon oxide for example is deposited on the semiconductor substrate 1 by the CVD process or the like, and thereafter it is treated by the photolithographic process and dry etching process to make a through-hall TH1 so as to expose part of the first wiring L1. Subsequently, a metallic film of tungsten for example is deposited on the semiconductor substrate 1 by the sputtering process, CVD process or the like, and thereafter it is abraded by the CMP process or the like so as to leave only the interior of the through-hall TH1 thereby to form a plug 19. Subsequently, films of titanium nitride, aluminum and titanium nitride for example are deposited in this order from the bottom on the semiconductor substrate 1 by the sputtering process or the like, and thereafter it is patterned by the photolithographic process and dry etching process, thereby forming second-layer wirings L2 (including the main bit line). The second wirings L1 are connected electrically through the plug 19 to the first wiring L1.

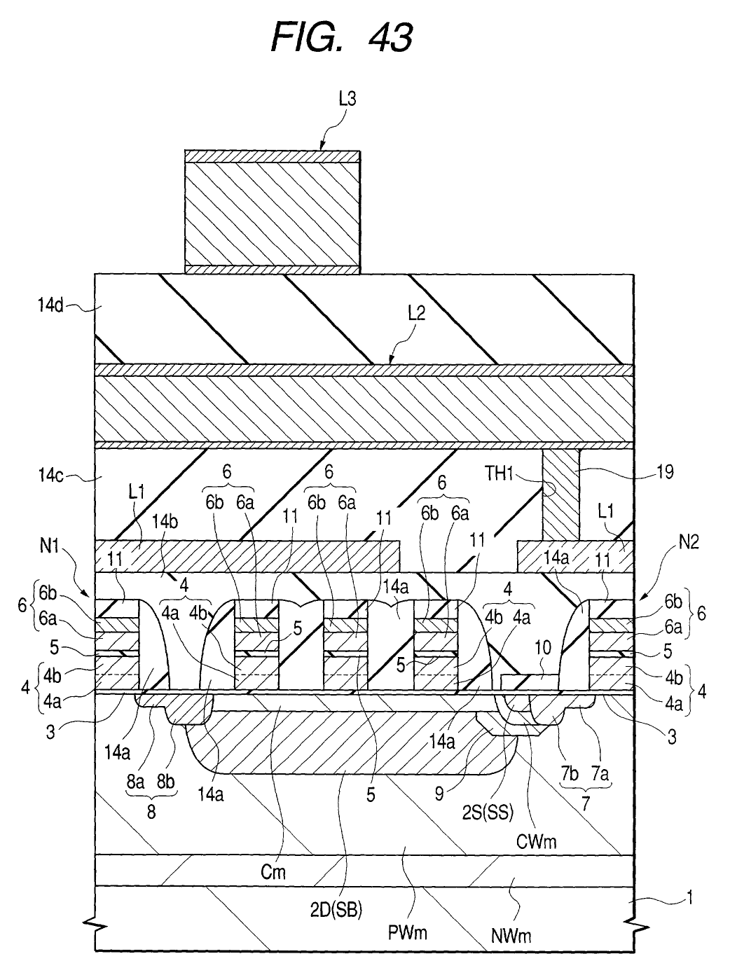

FIG. 43 shows the same cross section as FIG. 16 at the subsequent fabrication step.

An insulator film 14d of silicon oxide for example is deposited on the semiconductor substrate 1 by the CVD process or the like, and thereafter it is treated to make a through-hall (not shown) in the same manner as the through-hall TH1 so as to expose part of the second wiring L2. Subsequently, a plug of tungsten or the like is formed in the through-hall in the same manner as the plug 19, and thereafter a third-layer wiring L3 which is deposited films of titanium nitride, aluminum and titanium nitride for example is formed on the semiconductor substrate 1 in the same manner as the second wiring L2. The third wiring L3 is connected electrically through the plug to the second wiring L2. Subsequently, a surface protection film is formed on the semiconductor substrate 1, and thereafter it is treated to make openings to expose part of the third wiring L3. Finally, bonding pads are formed in the openings to complete the flash memory.

The foregoing first embodiment presents the following major effectiveness.

The inventive flash memory can have its memory cell channel length made even 0.1 μm or less, while keeping a distance between the n-type semiconductor regions 2S and 2D, whereby it can keep a source-drain punch-through breakdown voltage of 1 V or higher for the data readout operation.

The inventive flash memory can separate between the channel well regions CWm and the common p-well PWm, enabling the setting of the junction breakdown voltage between the n-type semiconductor region 2D and p-well PWm higher relatively to the source-drain punch-through breakdown voltage, whereby it can have a junction breakdown voltage between the n-type semiconductor region 2D and the p-well PWm for the data write operation.

The inventive flash memory facilitates the adjustment of threshold voltage due to the presence of the channel doped layer Cm which causes the current between the n-type semiconductor region pair 2S flowing deeply from the surface of the semiconductor substrate 1, whereby the injection of hot electrons decreases to prevent the decay of the gate insulation film 3 and the fluctuation of the threshold voltage.

The inventive flash memory can have a reduced width of the n-type semiconductor regions 2S (local source lines SS) in the channel direction and the width of the separation groove 17, while retaining the channel length to be the minimum working dimension F for example, whereby the bit line pitch can be made 3F or less.

The inventive flash memory has its n-type semiconductor region 2D (sub bit line SB) formed deep in the semiconductor substrate 1, enabling the setting of an intended impurity concentration independently of the source region, whereby the resistivity can be set lower relatively.

Embodiment 2

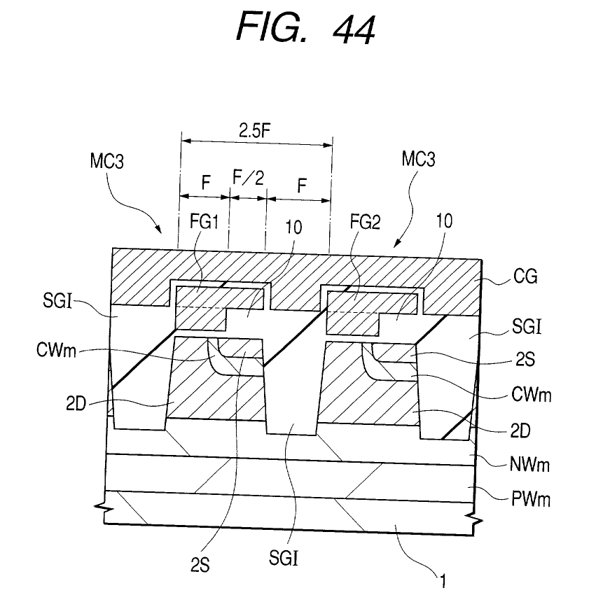

The memory cell structure based on the second embodiment of this invention will be explained with reference to FIG. 44. This figure shows the cross section of memory cells MC3 by cutting through the word line along its running direction.

The memory cell MC3 of this embodiment has an n-type semiconductor region 2S for the source region located to confront one sidewise portion of the floating gate electrode FG1 (FG2) on the semiconductor substrate 1, and the region 2S is covered by a channel well region CWm to have the DD structure. The floating gate electrode FG1 (FG2) is formed of two laminated conductor films, with the upper conductor film being wider than the lower conductor film, to present an L-shaped cross section. With the lower conductor film having a width in the channel direction equal to the minimum working dimension F, the upper conductor film having a width in the channel direction equal to half the minimum working dimension F, and the separation band SGI having a width in the channel direction equal to the minimum working dimension F, then the memory cell has a bit line pitch of 3F or less.

Based on the formation of the n-type semiconductor region 2S for the source region to confront one sidewise portion of the lower conductor film of the floating gate electrode FG on the semiconductor substrate 1, it is possible to reduce the bit line pitch and thus the cell area, whereby the memory array can have a higher integration density.

Embodiment 3

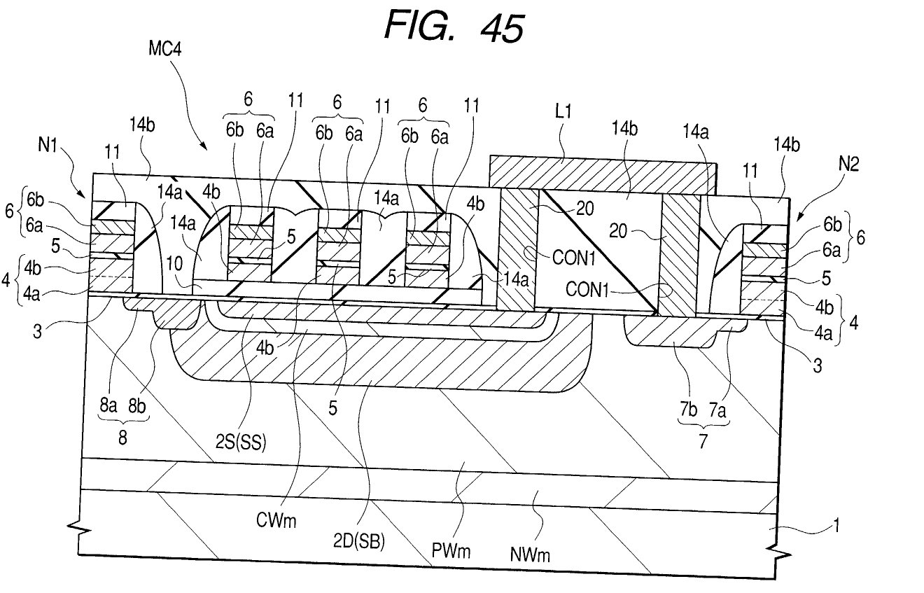

The memory cell structure based on the third embodiment of this invention will be explained with reference to FIG. 45. This figure shows the cross section of a memory cell MC4 by cutting through the source section along the bit line running direction.

The memory cell MC4 of this embodiment has its n-type semiconductor region 2S (local source line SS) for the source region covered completely by a channel well region CWm, which is separated from a common semiconductor region PWm by an n-type semiconductor region 2D. The local source line SS has its one end connected through a first-layer wiring to a part of n-type semiconductor region 7 which form the source-drain regions of the source-side selecting MOSFET N2. This connection may be made by use of plugs 20 which fill contact halls CON1 formed in the insulator film 14b for example as shown in the figure.

This structure enables the channel well region CWm to have a higher impurity concentration relatively to the common semiconductor region (p-well PWm), and it becomes possible to reduce the channel length of memory cell and raise the breakdown voltage between the n-type semiconductor region 2D and the semiconductor substrate 1 (p-well PWm) at the same time.

Embodiment 4

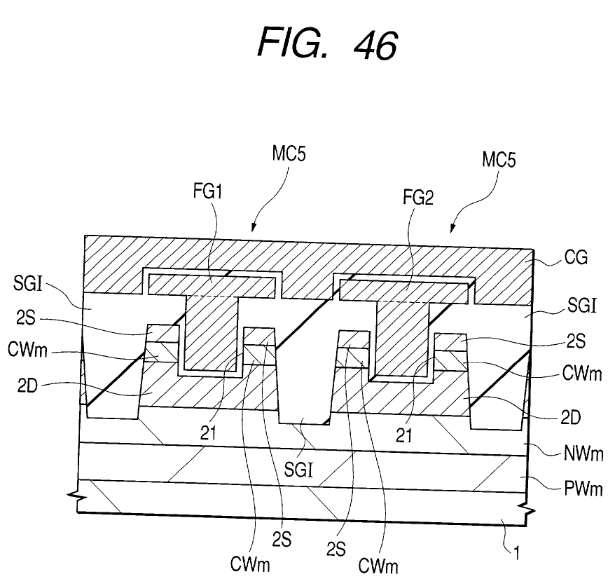

The memory cell structure based on the fourth embodiment of this invention will be explained with reference to FIG. 46. This figure shows the cross section of memory cells MC5 by cutting through the word line along its running direction.

The memory cell MC5 of this embodiment has its floating gate electrode FG1 (FG2) formed of conductor films of two layers to have a T-shaped cross section. The lower conductor film is buried in a groove 21 which is formed in the semiconductor substrate 1 to reach a deep n-type semiconductor region 2D for the drain region.

This structure of the exactly vertical channel direction (depth direction of the semiconductor substrate 1) increases the latitude of control for ion injection at the formation of the channel well regions CWm, and considerably facilitates the stabilization of operation current.

Although the present invention has been described in connection with the specific embodiments, the invention is not confined to these embodiments, but various alterations are obviously possible without departing from the essence of the invention.

For example, the present invention is not confined to discrete flash memory devices as explained in the foregoing embodiments, but it is also applicable to versatile semiconductor integrated circuit devices in which a flash memory and logic circuit for example are formed on a semiconductor substrate.

Among the affairs of the present invention disclosed in this specification, the major effectiveness is briefed as follows.

The inventive nonvolatile memory cell having a channel width of 0.1 μm or less can keep a source-to-drain punch-through breakdown voltage of 1 V or higher for the data readout operation and at the same time can have a drain to common p-well junction breakdown voltage of 6 V or higher for the data write operation. It can prevent the decay of tunneling oxide film and the fluctuation of threshold voltage. In consequence, the reliability of flash memories fabricated based on the process of 0.1 μm or less can be improved.

The inventive nonvolatile memory cell can have the width in channel direction of the source region and the width of SGI reduced smaller than the minimum working dimension, while retaining the channel length to be the minimum working dimension, thereby reducing the bit line pitch. In consequence, the higher integration density of flash memory can be accomplished.

The inventive nonvolatile memory cell can have the setting of lower resistivity for the drain region, and in consequence the speed-up of flash memory can be accomplished.

1. A semiconductor integrated circuit device comprising a flash memory which has a plurality of nonvolatile memory cells located in matrix arrangement on a semiconductor substrate, with said memory cells of each column having their source regions connected in parallel and their drain regions connected in parallel, and has a plurality of word lines which are formed to extend along the rows, each of said memory cells including:
a first gate electrode which is formed on said semiconductor substrate by being interposed by a first insulator film;
a second gate electrode which is formed on said first gate electrode by being interposed by a second insulator film;
source regions which are formed on said semiconductor substrate to confront two sidewise portions of said first gate electrode;
a drain region which is formed through channel well regions which are formed contiguously to said source regions; and
a common semiconductor region which is separated from said channel well regions by said drain region.

2. A semiconductor integrated circuit device including a flash memory which has a plurality of nonvolatile memory cells located in matrix arrangement on a semiconductor substrate, with said memory cells of each column having their source regions connected in parallel and their drain regions connected in parallel, and has a plurality of word lines which are formed to extend along the rows, each of said memory cells including:
a first gate electrode which is formed on said semiconductor substrate by being interposed by a first insulator film;
a second gate electrode which is formed on said first gate electrode by being interposed by a second insulator film;
a source region which is formed on said semiconductor substrate to confront one sidewise portion of said first gate electrode;
a drain region which is formed through a channel well region which is formed contiguously to said source region; and
a common semiconductor region which is separated from said channel well region by said drain region.

3. A semiconductor integrated circuit device according to claim 1 or 2, wherein a channel doped layer which is identical in conductivity type to said channel well region is formed beneath said first gate electrode on said semiconductor substrate.

4. A semiconductor integrated circuit device according to claim 1 or 2, wherein injection of charges from said semiconductor substrate into said first gate electrode is based on tunneling through said first insulator film from said channel well region.

5. A semiconductor integrated circuit device according to claim 1 or 2, wherein the voltage to be applied to the drain regions of nonvolatile memory cells aligning on unselected rows for the data write operation is higher relatively to the voltage applied to the drain regions of memory cells aligning on a selected row.

6. A semiconductor integrated circuit device according to claim 1 or 2, wherein said first gate electrode comprises a lower conductor film and an upper conductor film, with said upper conductor film being larger in width along the word line running direction than said lower conductor film.

7. A semiconductor integrated circuit device according to claim 1 or 2, wherein said first gate electrode comprises a lower conductor film and an upper conductor film, with said upper conductor film being larger in width along the word line running direction than said lower conductor film and said lower conductor film reaching the depth of said drain region.

8. A semiconductor integrated circuit device according to claim 1 or 2, wherein said source region is surrounded completely by said channel well region.

9. A semiconductor integrated circuit device according to claim 1 or 2, wherein said channel well region has a peak impurity concentration of 10¹⁸ cm⁻³ or more and the junction between said drain region and said common semiconductor region has an impurity concentration of about 1×10¹⁷ cm⁻³.

10. A semiconductor integrated circuit device according to claim 1 or 2 further including word lines each formed to interconnect the second gate electrodes of said memory cells aligning on a row, common source lines each formed to interconnect the source regions of memory cells aligning in a column, and common bit lines each formed to interconnect the drain regions of memory cells aligning in a column.

11. A semiconductor integrated circuit device according to claim 10, wherein said memory cells aligning in adjacent columns are separated electrically by a separation groove, with an insulator film being formed therein.

12. A semiconductor integrated circuit device according to claim 10, wherein said common source line is connected to one of the source and drain regions of a field effect transistor for a peripheral circuit, and said common bit line is connected to one of the source and the drain regions of another field effect transistor for the peripheral circuit.

13. A semiconductor integrated circuit device according to claim 10, wherein said common source line is connected to one of the source and the drain regions of a field effect transistor for a peripheral circuit, and said common bit line is connected to one of the source and the drain regions of another field effect transistor for the peripheral circuit, and a semiconductor region which is identical in conductivity type to said channel well region and lower in impurity concentration relatively to said channel well region is formed beneath the junction between said channel well region and one of the source and the drain regions of a field effect transistor for a peripheral circuit.

14. A semiconductor integrated circuit device according to claim 10, wherein said common source line is connected to one of the source and the drain regions of a field effect transistor for a peripheral circuit through a first-layer wiring, and said common bit line is connected to one of the source and the drain regions of another field effect transistor for the peripheral circuit.

15. A semiconductor integrated circuit device comprising:
a plurality of separation bands which are formed in parallel to each other to extend in a first direction on a main surface of the semiconductor substrate so as to divide the main surface into a plurality of elongated semiconductor island regions which extend in the first direction;
source regions, channel well regions and drain regions which are formed in said semiconductor island regions to extend in the first direction;
a common semiconductor region which is formed in the region at the bottom of said separation bands to have a pn junction with the lower portion of the drain regions of said semiconductor island regions;
a plurality of word lines which are formed in parallel to each other to extend across said semiconductor island regions in a second direction which intersects the first direction; and
first gate electrodes which are formed between said word lines and said semiconductor island regions at the intersections thereof by being insulated at the corresponding intersections from said semiconductor island regions by a first insulator film and from said word lines by a second insulator film,
said drain regions extending at a deep position of said semiconductor island regions beneath said channel well regions so as to separate said channel well regions from said semiconductor island regions, with nonvolatile memory cells being located at the intersections of said semiconductor island regions and said word lines.

16. A method of fabricating a semiconductor integrated circuit device which comprises a flash memory having a memory array structure, in which a plurality of nonvolatile memory cells are located in matrix arrangement on a semiconductor substrate, with said memory cells of each column having their source regions connected in parallel and their drain regions connected in parallel, and a plurality of word lines are formed to extend in the channel direction of nonvolatile memory cells,
said method comprising the steps of:
(a) forming drain regions by implanting impurity of a first conductivity type into a semiconductor substrate;
(b) forming a first insulator film on said semiconductor substrate;
(c) working a conductor film for first gate electrodes, which is deposited on said first insulator film, along a first direction;
(d) implanting impurity of a second conductivity type into said semiconductor substrate by using the conductor film for said first gate electrode as a mask, thereby forming channel well regions; and
(e) implanting impurity of the first conductivity type into said semiconductor substrate by using the conductor film for said first gate electrode as a mask, thereby forming source regions.

17. A method of fabricating a semiconductor integrated circuit device according to claim 16 further including the steps of:
(f) forming separation grooves in said semiconductor substrate by using the conductor film for said first gate electrodes and a third insulator film formed on the side wall of the conductor film as a mask;
(g) filling said separation grooves and recesses on the main surface of said semiconductor substrate with a fourth insulator film;
(h) working an upper-layer conductor film for said first gate electrodes, which is deposited on the said conductor film, along the first direction;
(i) forming a second insulator film on said upper-layer conductor film;
(j) forming a conductor film for second gate electrodes on said second insulator film; and
(k) working the conductor film for said second gate electrodes, said second insulator film and said upper-layer conductor film for said first gate electrodes along a second direction which intersects the first direction, thereby forming double-layer-gate electrodes of said memory cells.

18. A method of fabricating a semiconductor integrated circuit device according to claim 17 further including the steps of:
(l) working the conductor film for said second gate electrodes, said second insulator film and said double-layer conductor film for said first gate electrodes, thereby forming a gate electrode of a field effect transistor for a peripheral circuit; and
(m) forming a pair of semiconductor regions for said field effect transistor of the peripheral circuit on said semiconductor substrate.

19. A method of fabricating a semiconductor integrated circuit device according to claim 16, wherein said step (a) further includes the formation of a channel doped layer of the second conductivity type.

20. A method of fabricating a semiconductor integrated circuit device according to claim 16 further including the step, which precedes said step (b), of forming a groove in said semiconductor substrate so as to reach said drain regions in depth.

21. A method of fabricating a semiconductor integrated circuit device according to claim 18 further including the step of forming a semiconductor region, which is identical in conductivity type to said channel well region and lower in impurity concentration relatively to said channel well region, beneath the junction between said channel well region and one of the source and the drain regions of the field effect transistors of the peripheral circuit.

22. A semiconductor integrated circuit device including a nonvolatile semiconductor memory device which has a semiconductor substrate having a main surface and a plurality of nonvolatile memory cells located in matrix arrangement on the main surface of said semiconductor substrate, each of said memory cells including:
a floating gate electrode which is formed on the main surface of said semiconductor substrate by being interposed by a first insulator film;
a control gate electrode which is formed on said floating gate electrode by being interposed by a second insulator film;
a source region and a drain region which are formed by being spaced out from each other on the main surface of said semiconductor substrate;
a channel formation region which is located between the source region and the drain region to extend beneath said floating gate electrode on the main surface of said semiconductor substrate; and
a common semiconductor region for each of said memory cells which is identical in conductivity type to said channel formation region and is formed by being separated from said channel formation region by said drain region,
said semiconductor memory device further including:
a plurality of word lines each formed on said semiconductor substrate to interconnect the control gate electrodes of said memory cells aligning on a row;
a plurality of bit lines each formed on said semiconductor substrate to interconnect the drain regions of said memory cells aligning on a row; and
a plurality of source lines each formed on said semiconductor substrate to interconnect the source regions of said memory cells aligning in a column,
said memory cells aligning in each column being connected in parallel to each other.

23. A semiconductor integrated circuit device according to claim 22, wherein the bit line and the source line of each column are formed by the parallel arrangement of the drain region and the source region which are formed commonly to said memory cells of each column.

24. A semiconductor integrated circuit device according to claim 23, wherein said memory cells aligning in adjacent columns are separated electrically by an insulation-separation groove, with an insulator film being formed therein.

25. A semiconductor integrated circuit device according to claim 22, wherein injection of charges into said floating gate electrode is based on tunneling through said first insulator film from said channel well region.

26. A semiconductor integrated circuit device according to claim 25, wherein drain voltage to be applied to the drain regions of said memory cells aligning on unselected rows is higher relatively to the voltage applied to the drain regions of memory cells aligning on a selected row.

27. A semiconductor integrated circuit device according to claim 23, wherein said drain region formed commonly to memory cells of each column is located, in said semiconductor substrate, deeper than said common source region is located thereby to surround said channel formation region, and said common semiconductor region is formed, in said semiconductor substrate, deeper than said drain region is formed.
